(19) United States
(12) Patent Application Publication
(10) Pub. No.: US 2023/0140376 A1
(43) Pub. Date: May 4, 2023

(54) Magnetic Wood and Uses Thereof

(71) Applicant: Northeastern University, Boston, MA (US)

(72) Inventors: Hongli Zhu, Arlington, MA (US); Nian-Xiang Sun, Winchester, MA (US)

(21) Appl. No.: 17/515,146

(22) Filed: Oct. 29, 2021

(51) Int. Cl. B27K 3/00; B27K 3/02; B27K 3/26; B27K 5/02

(52) U.S. Cl. CPC B27K 3/007; B27K 3/02; B27K 3/26; B27K 5/02

(57) ABSTRACT

Provided herein are compositions comprising wood and an inorganic magnetic material which is uniformly distributed throughout the wood, as well as methods of providing electromagnetic interference and/or shielding using the compositions (e.g., for use in construction, defense information security, and aerospace applications). Also provided herein is a process for preparing the compositions.

### RELATED APPLICATION

This application claims the benefit of U.S. Provisional Application No. 63/107,133, filed on Oct. 29, 2020. The entire teachings of this application are incorporated herein by reference.

### BACKGROUND

Currently, booming telecommunications technology and digital systems bring convenience to human life and generate a large amount of electromagnetic interference (EMI), which not only affects information security but also causes harmful electromagnetic radiation pollution (Liang, C.; Song, P.; Qiu, H.; Zhang, Y.; Ma, X.; Qi, F.; Gu, H.; Kong, J.; Cao, D.; Gu, J., Nanoscale 2019). To address these electromagnetic pollution problems, various EMI shielding materials have been developed (Wu, H.; Wu, G.; Ren, Y.; Yang, L.; Wang, L.; Li, X., Journal of Materials Chemistry C 2015, 3 (29), 7677-7690; Gan, W.; Gao, L.; Zhan, X.; Li, J., RSC Advances 2015, 5 (57), 45919-45927; Liang, C.; Song, P.; Qiu, H.; Huangfu, Y.; Lu, Y.; Wang, L.; Kong, J.; Gu, J., Composites Part A: Applied Science and Manufacturing 2019, 124, 105512). Among them, iron oxide, a typical magneto-dielectric material with both magnetic loss and dielectric loss, is one of the most attractive microwave-absorbing materials (Lou, Z.; Li, Y.; Han, H.; Ma, H.; Wang, L.; Cai, J.; Yang, L.; Yuan, C.; Zou, J., ACS Sustainable Chemistry & Engineering 2018, 6 (11), 15598-15607).

Wood is a natural lightweight composite that has excellent mechanical properties and unique mesostructures resulting from its natural growth (Song, J.; Chen, C.; Zhu, S.; Zhu, M.; Dai, J.; Ray, U.; Li, Y.; Kuang, Y.; Li, Y.; Quispe, N., Nature 2018, 554 (7691), 224). One of the best features of wood is its structural anisotropy with vertically aligned channels, which are used to pump ions, water, and other ingredients through the wood trunk to meet its metabolic needs (Chen, C.; Xu, S.; Kuang, Y.; Gan, W.; Song, J.; Chen, G.; Pastel, G.; Liu, B.; Li, Y.; Huang, H., Advanced Energy Materials 2019, 9 (9), 1802964).

Different approaches for the modification and functionalization of wood have been studied to improve wood quality and raise its value. Natural wood has been utilized to fabricate functional transparent wood composites that exhibit extraordinary anisotropic optical and mechanical properties (Jiang, F.; Li, T.; Li, Y.; Zhang, Y.; Gong, A.; Dai, J.; Hitz, E.; Luo, W.; Hu, L., Advanced Materials 2018, 30 (1), 1703453; Zhu, M.; Song, J.; Li, T.; Gong, A.; Wang, Y.; Dai, J.; Yao, Y.; Luo, W.; Henderson, D.; Hu, L., Advanced materials 2016, 28 (26), 5181-5187). A simple strategy for the large-scale fabrication of artificial polymeric woods with outstanding performance, including mechanical strength comparable to that of natural wood, preferable corrosion resistance to water and acid with no decrease in the mechanical properties, as well as excellent thermal insulation and fire retardancy has been reported. A stiff, thermally stable, and highly anisotropic carbonized wood composite with EMI shielding effectiveness by incorporating silver nanowires (AgNWs) has also been prepared (Yu, Z.-L.; Yang, N.; Zhou, L.-C.; Ma, Z.-Y.; Zhu, Y.-B.; Lu, Y.-Y.; Qin, B.; Xing, W.-Y.; Ma, T.; Li, S.-C., Science advances 2018, 4 (8), eaat7223; Yuan, Y.; Sun, X.; Yang, M.; Xu, F.; Lin, Z.; Zhao, X.; Ding, Y.; Li, J.; Yin, W.; Peng, Q., ACS applied materials & interfaces 2017, 9 (25), 21371-21381). Although the carbon composite is lightweight with good EMI shielding performance, AgNWs are expensive, and a high loading of AgNWs would result in complicated processing, large amounts of agglomerates, and poor mechanical strength.

For general application, wood materials usually need preservation and coloring, where the coloration is typically obtained by impregnating wood with organic pigments or coating wood sheets with toxic and volatile organic varnish (Yeniocak, M.; Goktas, O.; Colak, M.; Ozen, E.; Ugurlu, M., Maderas. Ciencia y tecnologia 2015, 17 (4), 711-722). These solutions are ineffective when exposed to UV radiation or heating.

Thus, materials constructed from wood are often covered in additional materials (e.g., paint). The purposes for painting wooden material include, but are not limited to, protecting the wood from pests, waterproofing the wood, blocking harmful UV light, cooling the interior of a dwelling, and adding aesthetic value to the home. Paint suffers from a number of drawbacks, such as expense from continued applications, susceptibility to heat, susceptibility to weather conditions, and susceptibility to UV radiation.

With the development of state-of-the-art techniques, iron oxide pigment has become the second most used inorganic pigment, and it includes multiple colors such as iron oxide red, iron oxide yellow, iron oxide brown, and iron oxide black. In particular, iron oxide brown is widely used as a typical brown pigment (Hradil, D.; Grygar, T.; Hradilová, J.; Bezdička, P., Applied Clay Science 2003, 22 (5), 223-236; Guskos, N.; Papadopoulos, G.; Likodimos, V.; Patapis, S.; Yarmis, D.; Przepiera, A.; Przepiera, K.; Majszczyk, J.; Typek, J.; Wabia, M., Materials Research Bulletin 2002, 37 (6), 1051-1061; Grygar, T.; Bezdička, P.; Hradil, D.; Doménech-Carbó, A.; Marken, F.; Pikna, L.; Cepriá, G., Analyst 2002, 127 (8), 1100-1107).

Despite the progress made, limitations on the direct application of magneto-dielectric materials or conventional metal-based materials in EMI shielding fields still exist due to high density, material thickness, fabrication difficulty, and unsatisfactory shielding effectiveness.

Thus, there is a need for EMI shielding materials that are lightweight, construable, thermally stable, and have strong absorption capacities.

### SUMMARY

Provided herein are compositions comprising wood and an inorganic magnetic material which is uniformly distributed throughout the wood.

Also provided herein is a process for preparing a composition described herein, the process comprising mineralizing wood with an inorganic magnetic material.

Further provided herein is a method for providing electromagnetic interference (EMI) shielding, comprising providing a composition described herein between a source of electromagnetic radiation and a space to be shielded from the electromagnetic radiation, thereby shielding the space from the electromagnetic radiation.

The compositions provided herein display an optical colored appearance, and excellent EMI shielding effectiveness due to enhanced magnetic loss tangent. Due to wood's mesoporous and interconnected porous network structure, the compositions can achieve these enhanced effects in as little as about 3 mm of thickness. The magnetic wood compositions keep the original wood micro- and nanostructures, including the aligned cell walls and the inside cellulose fibers, and display saturation magnetization of at least about 4.5 emu/g. 3-Millimeter thick magnetic wood showed about 5 to about 10 dB (or about 7 to about 10-fold) enhanced electromagnetic wave attenuation across X-band of about 8 to about 12 GHz compared to nonmagnetic wood of the same thickness. The compositions provided herein also have the unexpected benefit of coloring the treated wood. This coloring provides additional benefits with respect to coloring that paint cannot provide, including, but not limited to, longevity of coloring, enhanced resistance to heat, enhanced resistance to weathering, and enhanced resistant to UV radiation. Assembling smaller magnetic wood blocks into a large wooden model is readily achievable and of importance for industrial applications. Because wood is ubiquitous and lightweight, the compositions described herein are highly attractive for large-scale EMI shielding applications for buildings and electronics in space, military, and civilian applications.

### BRIEF DESCRIPTION OF THE DRAWINGS

The patent or application file contains at least one drawing executed in color. Copies of this patent or patent application publication with color drawings will be provided by the Office upon request and payment of the necessary fee.

The foregoing will be apparent from the following more particular description of example embodiments.

FIG. 1A shows a hardwood block prior to slicing.

FIG. 1B shows the hardwood block of FIG. 1A after being sliced into pieces approximately 3 mm in thickness.

FIG. 2 shows wood slices submerged in a bleaching solution (H₂O₂, 2.5 M) in which the slices were boiled without stirring.

FIG. 3 shows wood slices after the cooking and bleaching process, where the slices exhibit a white color and are translucent.

FIG. 4 shows a comparison of wood slices before and after bleaching.

FIG. 5A is a scanning electron microscope (SEM) image showing uniform distribution of iron oxide (Fe₃O₄) particles in the inner surface of the lumen walls of the wood, and a layer of magnetic particles deposited on the cell wall of the wood.

FIG. 5B is a SEM image showing a portion of the SEM image from FIG. 5A magnified.

FIG. 5C is a SEM image showing a portion of the SEM image from FIG. 5B magnified.

FIG. 5D is a SEM image showing a portion of the SEM image from FIG. 5C magnified.

FIG. 6A shows high-resolution O 1s spectra of natural wood, delignified wood, and magnetic wood.

FIG. 6B shows high-resolution C 1s spectra of natural wood, delignified wood, and magnetic wood.

FIG. 7A shows the magnetization curve (magnetization versus magnetic field) of natural wood at room temperature.

FIG. 7B shows the magnetization curve (magnetization versus magnetic field) of delignified wood at room temperature.

FIG. 8A shows a return loss curve (S₁₁) of an ultra-wideband (UWB) antenna covered with wood, delignified wood, or magnetic wood, or uncovered.

FIG. 8B shows transmission loss (S₂₁) between a horn antenna and an UWB antenna covered with wood, delignified wood, or magnetic wood, or uncovered.

FIG. 9A shows a photograph of natural wood.

FIG. 9B shows a photograph of delignified wood.

FIG. 9C shows a photograph of magnetic wood.

FIG. 9D is a cross-section SEM image of natural wood, and shows the alignment of the microchannels in the longitudinal section (parallel to the channel direction).

FIG. 9E is a high-magnification cross-section SEM image of natural wood, in which some secondary pores in the radial direction are seen.

FIG. 9F is a cross-section SEM image of delignified wood, and shows that the longitudinal section (parallel to the channel direction) exhibited a loose and porous structure.

FIG. 9G is a high-magnification cross-section SEM image of delignified wood, and shows that the secondary pores became more open after lignin removal.

FIG. 9H is a cross-section SEM image of magnetic wood, and shows the longitudinal section (parallel to the channel direction) with nanosized iron oxide particles distributed inside the cell wall.

FIG. 9I is a high-magnification cross-section SEM image of magnetic wood, and shows iron oxide nanoparticles covered the wood surface, with some being embedded in or were even blocking the secondary pores.

FIG. 10A is a photograph of the surface of magnetic wood.

FIG. 10B is a photograph of the cross-section of the magnetic wood pictured in FIG. 10A.

FIG. 10C is an SEM image of the magnetic wood pictured in FIGS. 10A and 10B.

FIG. 10D shows an elemental map of the magnetic wood pictured in FIGS. 10A and 10B for oxygen.

FIG. 10E shows an elemental map of the magnetic wood pictured in FIGS. 10A and 10B for carbon.

FIG. 10F shows an elemental map of the magnetic wood pictured in FIGS. 10A and 10B for iron.

FIG. 10G shows X-ray photoelectron spectroscopy (XPS) spectra of natural wood, delignified wood, and magnetic wood.

FIG. 10H shows high-resolution Fe 2p spectra of natural wood, delignified wood, and magnetic wood.

FIG. 11A shows X-ray powder diffraction (XRPD) spectra for natural wood, delignified wood, and magnetic wood.

FIG. 11B shows Fourier transform infrared (FTIR) spectra for natural wood, delignified wood, and magnetic wood.

FIG. 11C shows thermogravimetric (TG) curves for natural wood, delignified wood, and magnetic wood.

FIG. 11D shows derivative thermogravimetric (DTG) curves for natural wood, delignified wood, and magnetic wood.

FIG. 12A shows a schematic illustration of the setup for an EMI effectiveness measurement.

FIG. 12B shows a magnetization curve of a magnetic wood sample at room temperature.

FIG. 12C shows normalized S₂₁ attenuation of natural wood, delignified wood, and magnetic wood.

FIG. 12D is a schematic diagram of electromagnetic wave transfer across magnetic wood, illustrating EMI shielding.

FIG. 13 is a schematic illustration of fabrication of magnetic wood with EMI shielding property: (a) hardwood tree; (b) natural wood before delignification; (c) delignified wood via the cooking and bleaching process for lignin removal; (d) magnetic wood obtained from the inorganic mineralization process; (e) schematic of the EMI shielding effect of the lightweight magnetic wood model, which is assembled with smaller individual magnetic wood blocks for scalable practical application. As the electromagnetic incident waves strike the surface of the magnetic wood, some waves are immediately reflected, and some waves are absorbed (dotted arrow).

FIG. 14A shows a comparison of the color changes of hardwood during the cooking process.

FIG. 14B shows a comparison of the color changes of hardwood during the bleaching process.

FIG. 14C shows delignified wood slices immersed in deionized water prior to the mineralization process.

FIG. 14D shows clean wood slices mineralized by performing alternating incubation cycles with 0.5 mol/L FeSO₄ and Na₂CO₃ solutions.

FIG. 14E shows magnetic wood after rinsing with deionized water.

FIG. 15 shows (a) a tree, a standard source of cellulose; (b) aligned cellulose nanofibrils (aCNF) and their structure; (c) a mineralization process; and (d) mineralized aligned cellulose nanofiber (m-aCNF) obtained from mineralization process depicted in (c) and its SEM micrograph, showing an aligned mineralized structure.

FIG. 16A shows a photograph of a 50 mm diameter hydrogel sample.

FIG. 16B shows the hydrogel sampled of FIG. 16A under a loaded weight of 500 g. The hydrogel maintained its structural integrity and did not collapse.

FIG. 16C is an SEM image of an aCNF fiber before mineralization. The arrows indicate well-aligned cellulose nanofibers.

FIG. 16D is a magnified SEM image of the aCNF fiber from the area marked with a rectangle in FIG. 16C. The arrows indicate well-aligned cellulose nanofibers.

FIG. 17A is a cross-sectional SEM image of the m-aCNF after 28 days of mineralization in PAA mineralizing solution.

FIG. 17B shows an elemental map for carbon of the m-aCNF after 28 days of mineralization in PAA mineralizing solution.

FIG. 17C shows an elemental map for phosphorous of the m-aCNF after 28 days of mineralization in PAA mineralizing solution.

FIG. 17D shows an elemental map for calcium of the m-aCNF after 28 days of mineralization in PAA mineralizing solution.

FIG. 17E is a SEM image from the marked area in FIG. 17A.

FIG. 17F is a SEM image from the marked area in FIG. 17E. The arrows indicate the aligned mineral nanocrystals with the direction of the nanofibers.

FIG. 17G is a bright-field transmission electron microscope (TEM) micrograph showing high infiltration of aligned nanocrystals in the cellulose fibrils.

FIG. 17H is a dark-field TEM micrograph showing high infiltration of aligned nanocrystals in the cellulose fibrils.

FIG. 17I is a selected area diffraction (SAED) analysis of the obtained nanocrystals, and shows characteristic patterns of oriented Hap with arcing of the (002) plane.

FIG. 18A is XRD spectra of m-aCNT, nonmineralized aCNF (black), and HAp disk, and shows that nm-aCNF showed characteristic peaks of HAp from the (002), (211), (300), (130), and (222) planes.

FIG. 18B shows ATR-FTIR spectra for aCNF and m-aCNF gels. Characteristic peaks of cellulose and carbonated HAp are labeled.

FIG. 19A is a cross-sectional SEM image of non-aligned cellulose nanofibers before mineralization.

FIG. 19B is a magnified SEM image of FIG. 19A.

FIG. 19C is a SEM image of materials with nonaligned cellulose fibers after 28 days of mineralization in PAA mineralizing solution.

FIG. 19D is a magnified SEM image of FIG. 19C.

FIG. 19E is a bright-field TEM micrograph showing randomly oriented mineral crystals.

FIG. 19F shows SAED analysis of the obtained nanocrystals showing multiple arcs for the (002) plane.

FIG. 20 shows thermogravimetric analysis of m-aCNF and aCNF materials. Values on each curve represent the percentage of weight sample remaining after competition of thermal disintegration.

FIG. 21A is a schematic illustration of the nanoindentation test process.

FIG. 21B is a representative nanoindentation load-displacement graph for m-aCNF and aCNF samples in dry state.

FIG. 21C is a representative elastic modulus graph for m-aCNF and aCNF samples in dry state.

FIG. 21D is a representative hardness vs. penetration depth of the indenter curves for m-aCNF and aCNF samples in dry state.

FIG. 21E shows elastic modulus for m-aCNF, a-CNF, human dentin, and mouse cortical bone in dry and rehydrated states. Values with “a” or “A” had no statistically significant differences in dry or rehydrated state, respectively.

FIG. 21F shows the hardness of m-aCNF, a-CNF, human dentin, and mouse cortical bone in dry and rehydrated states. Values with “a” or “A” had no statistically significant differences in dry or rehydrated state, respectively.

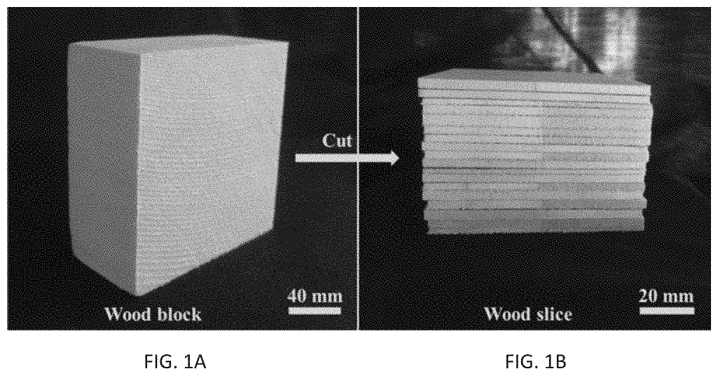

### DETAILED DESCRIPTION

A description of example embodiments follows.

### Compositions

Provided herein are compositions comprising wood and an inorganic magnetic material (e.g., a magnetic metal material) which is uniformly or substantially uniformly (e.g., uniformly) distributed throughout the wood, including wood compositions that have been mineralized with one or more inorganic magnetic materials (e.g., magnetic metal materials), e.g., according to a process disclosed herein. In some aspects, the wood is impregnated with the inorganic magnetic material.

Wood is a natural, lightweight composite that has excellent mechanical properties and unique mesostructures resulting from its natural growth. One feature of wood is its structural anisotropy with vertically aligned channels, which are used to pump ions, water, and other ingredients through the wood trunk to meet its metabolic needs. Generally, there are three primary chemical components in wood: cellulose, hemicellulose and lignin. Lignin is typically attributed with providing rigidity and brown color to natural wood. Delignified wood is thus often soft and white, and contains open micro- to nano-sized pores. Wood can also be mineralized, e.g., using an inorganic mineralization process. When wood is mineralized with a magnetic material, such as a magnetic metal material, magnetic wood can be obtained. When such material is a pigment, as iron oxide, for example, dark brown magnetic wood can be obtained through the mineralization process. “Wood”, as used herein, is meant to encompass wood in all of these forms. Thus, examples of wood include raw or natural wood, delignified wood and magnetic wood. Wood, including raw wood, delignified wood, and magnetic wood, can be in the form of wood chips, bark chips, sawdust, wood planks, wood blocks, wood slices, or the like.

Accordingly, in some aspects, wood is raw or natural wood.

The terms “raw wood” and “natural wood” are used interchangeably herein, and each refers to wood that has not been chemically modified. Typically, these terms refer to wood containing the complex polymers collectively known as lignin.

In some aspects, wood is delignified.

As used herein, the term “delignified wood” refers to wood wherein the lignin has been totally or substantially removed from the wood (e.g., by means disclosed herein). Delignification of wood beneficially results in increased space in the wood (e.g., in pores of the wood and/or the intermycelial space in the cell wall). Preferably, lignified wood maintains the mesostructures resulting from its natural growth, in particular, the micro- and nanostructures of natural or raw wood.

Thus, in further aspects, delignified wood has the micro- and nanostructures of natural wood, e.g., the aligned cell walls and/or inside cellulose fibers of natural wood.

As used herein to describe the structure of wood, the phrase “micro- and nanostructures” refers to the mesostructure of natural wood, and includes, for example, the interconnected pore network, aligned cell walls and/or cellulose fibers of natural wood.

The terms “a,” “an,” and “the” and the like used herein include both the singular and plural unless otherwise indicated or clearly contradicted by the context. Thus, “an inorganic magnetic material” includes one or more inorganic magnetic materials. Further, each inorganic magnetic material can be the same or different.

As used herein, the phrase “inorganic magnetic material” refers to an inorganic compound (e.g., metal-, such as transition metal- and/or earth metal-, based compound) that has or induces a magnetic field. In some embodiments, the magnetic material has a naturally occurring magnetic field. In some embodiments, the magnetic material has a magnetic field that must be induced (e.g., via application of an electric current). Non-limiting examples of magnetic metal materials include: iron, nickel, copper, cobalt, gadolinium, samarium, and neodymium, or an oxide, mineral or salt thereof, or a combination of the foregoing.

In some aspects, the inorganic magnetic material is a magnetic metal material. In further aspects, the inorganic magnetic material (e.g., magnetic metal material) is a transition metal or rare earth metal, or a salt or mineral (e.g., oxide) thereof, or a combination of any the foregoing. In yet another aspect, the inorganic magnetic material is a transition metal, a salt or mineral (e.g., oxide) thereof, or a combination of any of the foregoing. In still another aspect, the inorganic magnetic material is iron oxide, nickel oxide, copper oxide, cobalt oxide, a salt or mineral thereof, or a combination of any of the foregoing. In a particular aspect, the inorganic magnetic material is iron oxide.

In some aspects, the inorganic magnetic material is in the form of nanoparticles.

In an aspect, the compositions are anisotropic (e.g., structurally anisotropic). In further aspects, the compositions maintain the structural anisotropy of raw wood.

In an aspect, the composition is between about 1% and about 50% by weight inorganic magnetic material, e.g., between about 5% and about 40%, between about 10% and about 40%, between about 10% and about 25%, between about 15% and about 20%, about 15%, about 16%, about 17%, about 18%, about 19%, or about 20% by weight inorganic magnetic material. In yet further aspects, the composition is about 18% by weight inorganic magnetic material.

In an aspect, the composition is between about 50% and about 99% by weight wood, e.g., between about 60% and about 95%, between about 60% and about 90%, between about 75% and about 90%, between about 80% and about 85%, about 80%, about 81%, about 82%, about 83%, about 85%, or about 86% by weight wood. In yet further aspects, the composition is about 82% by weight wood.

Any combination of the aforementioned ranges are also envisioned.

As used herein the term “about” is used herein to mean approximately, roughly, around, or in the region of. When the term “about” is used in conjunction with a numerical range, it modifies that range by extending the boundaries above and below the numerical values set forth. In general, the term “about” is used herein to modify a numerical value above and below the stated value by a variance of 20 percent up or down (higher or lower), e.g., 10 percent up or down, 5 percent up or down, 4 percent up or down, 3 percent up or down, 2 percent up or down, or 1 percent up or down.

In another aspect, the composition shows at least about five times, e.g., at least about six times, at least about seven times, at least about 8 times, at least about nine times, or at least about 10 times, enhanced electromagnetic wave attenuation across X-band 8-12 GHz compared to non-magnetic wood (e.g., raw wood).

In another aspect, the composition further comprises one or more additional dyes and/or pigments. Pigments commonly used to color wood are widely available and include, but are not limited to, pigments colored purple (e.g., ultramarine violet (Al); han purple (Cu); cobalt violet; purple of cassius (Au), etc.), blue (e.g., cobalt blue; Egyptian blue (Cu); Prussian blue (Fe); etc.), green (e.g., cadmium green; chrome green (Cr); Scheele's green (Cu); etc.), yellow (e.g., orpiment (As); primrose yellow (Bi); naples yellow (Pb); etc.), orange (e.g., bismuth vanadate orange; cadmium pigments; etc.), red (e.g., red ochre (Fe); cinnabar (Hg); burnt sienna (Fe); etc.), and white (e.g., antimony white; lithopone (Ba); cremnitz white (Pb); etc.).

The compositions (e.g., magnetic wood) described herein can be in the form of a sheet, a tile, a board, a block, a plank or a slice, or a multi-layer composite of any one or more of the foregoing. The form (e.g., sheet, tile, board, block, plank, or slice) can have any shape or size. Selecting an appropriate shape and size for a particular use, such as construction, is within the abilities of a person skilled in the art.

The composition can also be in the form of a structure, such as a Faraday cage, comprising two or more smaller forms, such as those mentioned above. Means and methods of fastening, for example, two or more forms to one another are within the abilities of a person skilled in the art, and include glue, as well as other fasteners used in, for example, the construction industry, such as nails, screws, dowels, etc.

### Process of Preparation

Also provided herein are processes for preparing the compositions described herein. In one embodiment, the process comprises mineralizing wood with an inorganic magnetic material. In another embodiment, the process comprises delignifying wood (e.g., raw wood), thereby forming delignified wood; and mineralizing the delignified wood with the inorganic magnetic material.

As used herein, the terms “mineralizing” and “mineralization” refer to embedding inorganic magnetic material into wood. Mineralization may substantially or only partially embed the inorganic material in the wood pore structures, and may form embedded nanoparticles, microparticles, or wire-like structures. Preferably, mineralization results in uniform or substantially uniform distribution of inorganic magnetic material throughout a volume of wood (e.g., the treated volume of wood). In some aspects, the inorganic magnetic material is embedded throughout the wood in the micro- and nano-pore structures of the wood. Mineralizing may be effected, for example, by equilibration of a wood sample with a liquid medium comprising a higher concentration of inorganic magnetic material, mechanical action (e.g., sonication), chemically (e.g., as by oxidation), or a combination of one or more of the foregoing.

In an aspect, mineralizing comprises submerging wood in a liquid medium comprising inorganic magnetic material, or a precursor thereof; and sonicating the liquid medium. In an aspect, the liquid medium is a solution. In an alternative aspect, the liquid medium is a mixture. In a particular aspect, the liquid medium comprises water. The inorganic magnetic material can be selected from any of the inorganic magnetic materials described herein. Examples of precursors of inorganic magnetic material include any of the magnetic metal materials described herein, such as any metal, or salt or mineral (e.g., oxide) thereof, or a combination of the foregoing, such as Fe₃SO₄. In a particular aspect, the inorganic magnetic material, or a precursor thereof, is or comprises Fe₃SO₄.

In some aspects, delignifying comprises treating wood (e.g., raw wood) with a solution comprising a strong base, and bleaching the wood.

As used herein, the term “strong base” is a base that completely, or nearly completely, dissociates in an aqueous solution. Examples of strong bases include, but are not limited to, sodium hydroxide, potassium hydroxide, lithium hydroxide, rubidium hydroxide, calcium hydroxide, barium hydroxide, strontium hydroxide, and the like. In some aspects, the strong base is a hydroxide base, such as sodium hydroxide.

In some aspects, the solution comprising a strong base comprises NaOH and Na₂SO₃ in water. In some aspects, bleaching the wood comprises boiling the wood in a solution of H₂O₂ in water.

Because the mineralization process described herein embues the resulting wood with an optical colored appearance, also provided herein are methods for coloring wood. The methods comprise any of the mineralizing and, optionally, delignifying processes described herein. By varying the amount (e.g., as measured by concentration) and identity of the inorganic magnetic material and/or additional dyes and/or pigments in the composition, the color of the resulting magnetic wood can be tuned. For example, iron oxide may be used to provide a dark red, brown, black or yellow color, cobalt oxide may be used to provide a blue or olive-green color, copper oxide may be used to provide a black color, and nickel oxide may be used to provide a green color. Non-magnetic metallic compounds may be used for additional coloration to achieve colors such as purple (e.g., ultramarine violet (Al); han purple (Cu); cobalt violet; purple of cassius (Au), etc.), blue (e.g., cobalt blue; Egyptian blue (Cu); Prussian blue (Fe); etc.), green (e.g., cadmium green; chrome green (Cr); Scheele's green (Cu); etc.), yellow (e.g., orpiment (As); primrose yellow (Bi); naples yellow (Pb); etc.), orange (e.g., bismuth vanadate orange; cadmium pigments; etc.), red (e.g., red ochre (Fe); cinnabar (Hg); burnt sienna (Fe); etc.), and white (e.g., antimony white; lithopone (Ba); cremnitz white (Pb); etc.). Combinations of one or more of the foregoing can be used to provide color tuning. Such colored wood is expected to have enhanced longevity, enhanced UV resistance, enhanced weather resistance, and/or enhanced heat resistance compared to wood treated with standard paint.

### Methods of Use

The hierarchical and porous structure of wood is shown herein to be useful as a directional lightweight 3D organic scaffold for in situ incorporation of inorganic magnetic material (e.g., nanoparticles) through a mineralization process, which endows the resultant wood with favorable magnetic properties, excellent EMI shielding effectiveness, as well as an optical brown appearance. Further, the magnetic wood can meet requirements for large-scale production due to the use of low cost and vast resources, as well as scalable fabrication methods.

Accordingly, also provided herein is a method for providing electromagnetic interference shielding, comprising providing a composition described herein between a source of electromagnetic radiation and a space to be shielded from the electromagnetic radiation, thereby shielding the space from the electromagnetic radiation. In some aspects, the composition is in the form of construction material (e.g., planks) or a structure (e.g., a Faraday cage).

### EXEMPLIFICATION

### Example 1. Lightweight and Construable Magnetic Wood for Electromagnetic Interference Shielding

Abstract: Currently, due to the rapid development of communication technology, electromagnetic interference (EMI) and irradiation have become an emerging environmental pollutant. In this study, for the first time, hierarchical and porous structured wood was used as the lightweight 3D organic scaffold for the incorporation of magnetic iron oxide nanoparticles through in situ mineralization process that endows the woodblock with favorable appearance as well as magnetic and EMI shielding properties. The two-step process involves the removal of lignin from natural wood (delignification) via cooking and bleaching followed by inorganic mineralization. The resultant magnetic wood displays an optical brown appearance and possesses typical magnetic hysteresis behavior with a saturation magnetization of 4.5 emu/g for the whole wood. More importantly, the obtained magnetic wood is much lighter than traditional magnetic metal and construable for aerospace and military applications. Notably, the 3 mm thick magnetic wood shows 5-10 dB (or 7-10×) enhanced electromagnetic wave attenuation across the X-band of 8-12 GHz compared to nonmagnetic wood with the same thickness. The enhanced electromagnetic wave absorption of magnetic wood is mainly due to its enhanced magnetic loss tangent compared to nonmagnetic wood. This work provided an inspiring strategy to develop sustainable, lightweight, and environmentally friendly wood for high functional magnetic applications.

Introduction: Herein, the fabrication of magnetic wood based on the in situ deposition of magnetic Fe₃O₄ nanoparticles into a delignified wood template through an inorganic mineralization method is reported. The morphology, microstructure, chemical components, and magnetic characteristics of the obtained wood samples were investigated. The original structure of the wood was well preserved. The EMI shielding effect of magnetic wood with wood-ferrite multilayers was studied, and adequate signal strength attenuation was observed by applying magnetic wood as a shield during the test. A series of tests using air, natural wood, and delignified wood as control groups for EMI shielding effect studies were carried out, and magnetic wood was shown to be very effective across the X-band of 8-12 GHz. The study indicated that the magnetic wood is a promising candidate for various applications, such as a green shielding material in construction, furniture, decoration, packing, etc.

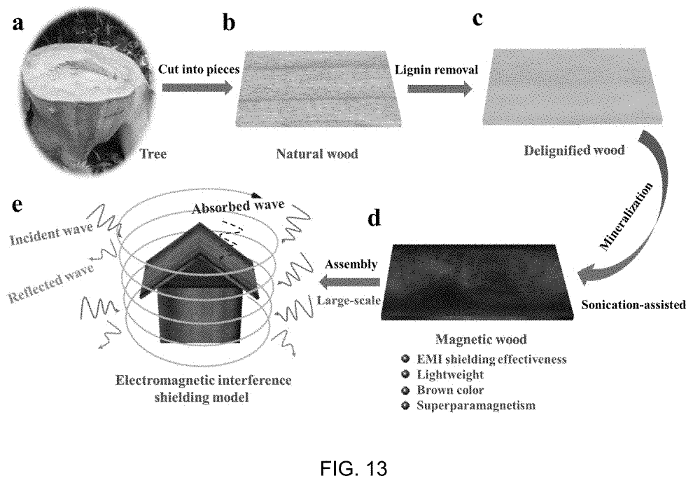

Results and Discussion: Inspired by the unique structure of natural wood, magnetic wood with an optical brown appearance and an excellent EMI shielding property was fabricated via lignin removal followed by an inorganic mineralization process, as shown in FIG. 13. Generally, there are three primary chemical components in the trees: cellulose, hemicellulose, and lignin (FIG. 13(a)). Among them, lignin provides the rigidity and brown color of natural wood (FIG. 13(b)). After lignin is removed, the wood (referred to as delignified wood in FIG. 13(c)) becomes soft and white, and micro- to nanosized pores in the wood are opened. These pores can then be used in a mineralization process, by impregnation with an inorganic material, to provide beneficial properties. Iron oxide, for example, can be well utilized since wood can be mineralized to create hierarchically structured organic-inorganic hybrid materials with novel properties. Furthermore, the literature has demonstrated that mineralized wood benefits from the structural integrity of natural wood, which has hierarchical pores that are beneficial for the deposition of inorganic minerals (Merk, V.; Chanana, M.; Gaan, S.; Burgert, I., Holzforschung 2016, 70 (9), 867-876). Different colors can be produced by the presence of goethite in petrified wood, and the intensity of the color depends on the quantity of iron-containing minerals (Mustoe, G.; Acosta, M., Geosciences 2016, 6 (2), 25).

Then, darker brown magnetic wood can be obtained through an inorganic mineralization process (FIG. 13(d)). Notably, assembling smaller magnetic wood blocks into a larger wooden model is readily achievable and crucial for industrial applications (FIG. 13(e)). Benefiting from the magnetic inorganic nanoparticles deposited on the interconnected porous network structured wood substrate, the wood-derived magnetic materials are expected to exhibit excellent EMI shielding performance. The shielding property is due to the distinctive self-assembling anisotropic morphology of inorganic nanoparticles formed on the inner surface of the wood lumen walls, which leads to the construction of a wood-ferrite multilayer structure. This multilayer structure can provide large magnetic loss tangent, optimal impedance matching, and an interconnected 3D network for electromagnetic wave absorption, reflection, and attenuation.

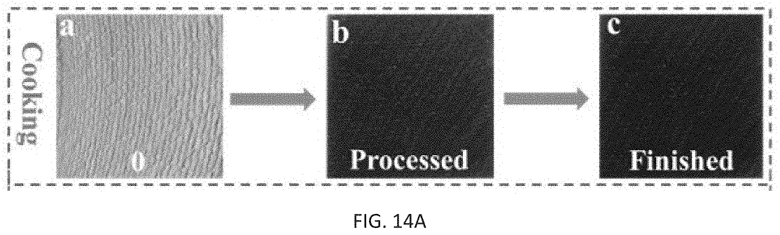

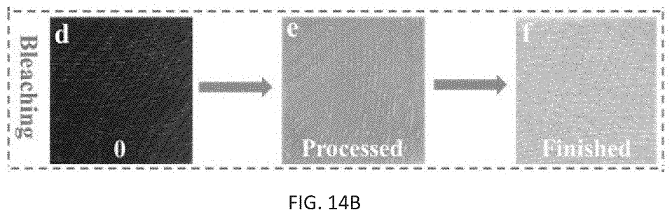

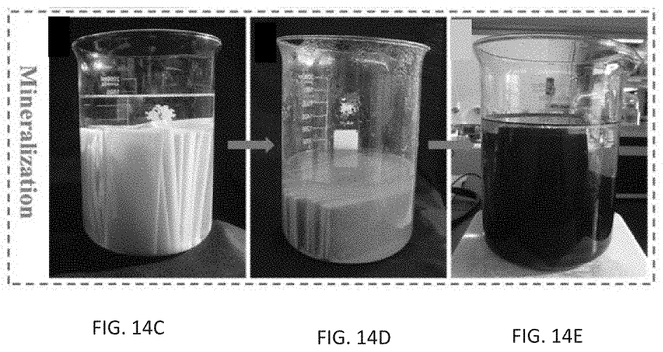

At the start of the fabrication process, wood slices with a thickness of 3 mm were obtained by cutting a hardwood block along the longitudinal direction (tree growth direction); these slices were then used as the basic material for magnetic wood preparation. The natural wood has a pale-yellow color due to the light absorption capability of lignin. A facile two-step process to remove the lignin from natural wood was used. Wood slices were soaked in a boiling solution containing NaOH and Na₂SO₃ (FIG. 14A) to dissolve part of the lignin content, which is a common chemical process used in the pulping industry. Then, the wood slices were transferred into a boiling H₂O₂ solution to further remove the remaining lignin (FIG. 14B). The color in the wood slices can be used to indicate the amount of lignin presented in the bulk surface of the wood since lignin is colored and cellulose is colorless. After delignification, the wood slice becomes completely white, demonstrating successful lignin removal. The process of obtaining the delignified wood is simple, which means fabricating a large amount of wood pieces at the same time is applicable in industry. Magnetic wood was then produced via an inorganic mineralization process, which is entailed on alternating incubation cycles with a metal salt precursor (e.g., 0.5 mol/L FeSO₄) and Na₂CO₃ solutions assisted by moderate sonication (FIG. 14C, FIG. 14D, and FIG. 14E).

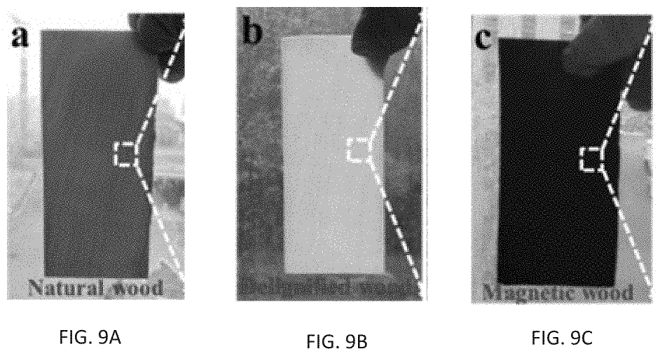

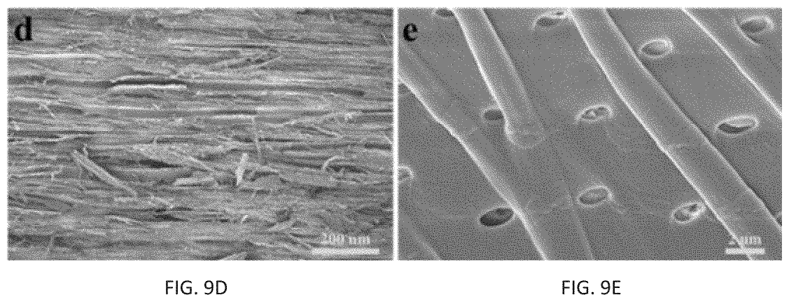

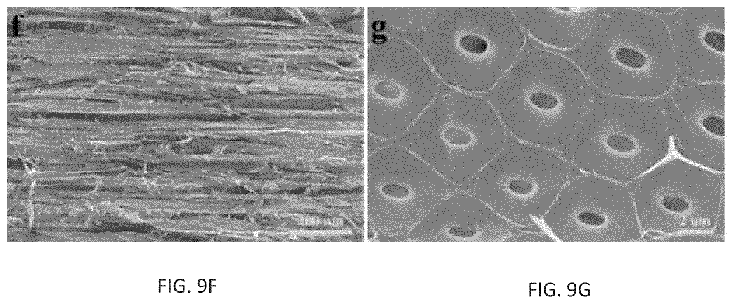

The morphology and microstructure of natural wood, delignified wood, and magnetic wood were also systematically investigated. As shown in FIG. 9A and FIG. 9D, the vertically aligned fiber tracheids and large-lumen vessels can be clearly seen in the longitudinal sections of the pale yellow natural wood. The wood cell wall is comprised mainly of cellulose, hemicelluloses, and lignin, and they intertwine with each other to provide the necessary mechanical integrity to the bulk wood. Such 3D hierarchical wood scaffold with special structural anisotropy shows great potential for further functionalization. The magnified scanning electron microscopy (SEM) image also shows the smaller pits on the inner surface of the lumen (FIG. 9E), representing the secondary pores. These secondary pores enable material transport in the radial direction of the wood trunk. FIG. 9B shows a photograph of the delignified wood block after lignin removal. The yellowish wood block becomes white after delignification, indicating the successful removal of dark-colored lignin, while the colorless polysaccharides are left behind. The delignification process also leads to significant changes in the morphology and microstructure of the wood block. The original compact cell wall evolved into a loosened skeleton with numerous pores generated in the wall, as shown in FIG. 9F. However, the microstructure with well-defined channels was well preserved after the delignification process. The high-magnification SEM image further reveals the changes in the microstructure of the cell wall (FIG. 9G), and it is noted that the small pores became more open after lignin removal. FIG. 9C shows magnetic wood obtained after the inorganic mineralization process, displaying an optical dark brown appearance. The cross-section SEM image revealed that nanosized iron oxide particles were distributed inside the cell wall (FIG. 911). In the high-magnification SEM images, it was observed that the iron oxide nanoparticles uniformly covering the wood surface, and some were embedded in or even blocking the secondary pores (FIG. 9I). The nanosized iron oxide particles was generated from the chemical, hydrolysis, and oxidation reactions of FeSO₄ and Na₂CO₃ substance.

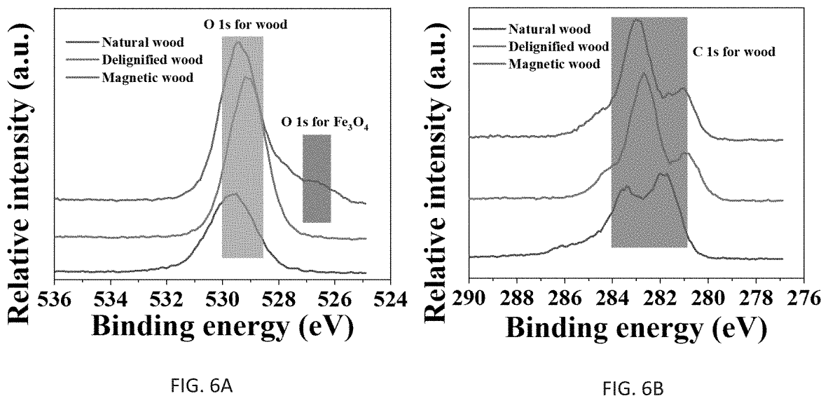

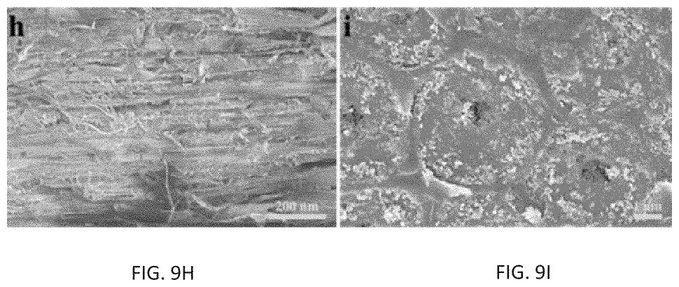

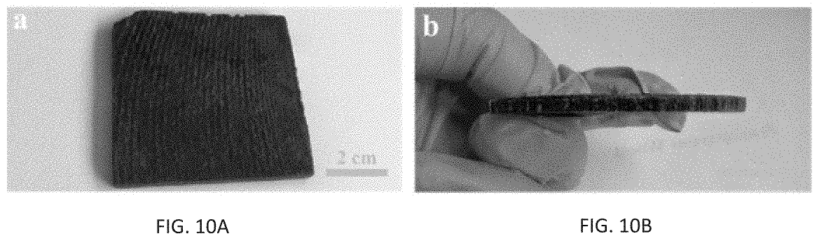

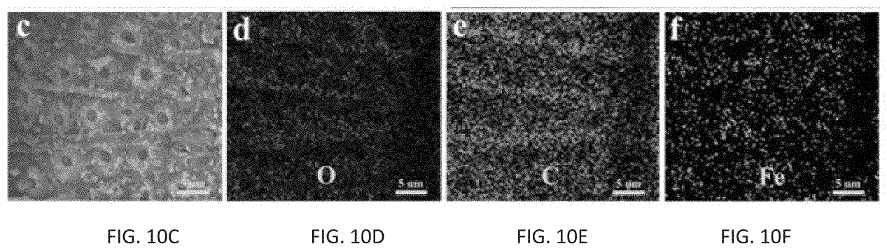

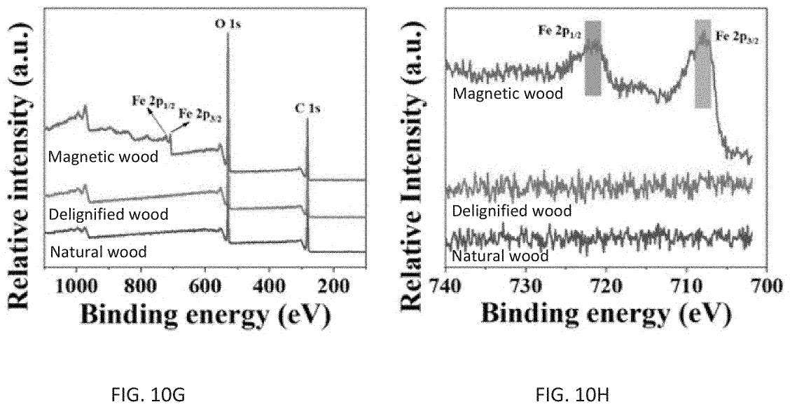

FIG. 10A and FIG. 10B show an optical brown appearance on both the surface as well as the cross-section of the magnetic wood, further indicating that iron oxides nanoparticles are uniformly distributed in the wood. Additionally, corresponding elemental mapping images of O, C, and Fe of the magnetic wood were obtained and are shown in FIG. 10C, FIG. 10D, FIG. 10D, and FIG. 10F. Based on the consistent distribution of Fe element in FIG. 10F, Fe was successfully incorporated into the delignified wood after the inorganic mineralization process. The presence of iron oxide was confirmed according to the results obtained from X-ray photoelectron spectroscopy (XPS) measurements because core electron lines of ferrous and ferric ions are both detected and are distinguishable from each other in the XPS spectra (FIG. 10G). The XPS spectra also verified that the natural wood and delignified wood contain mainly O and C, while the magnetic wood contains O, C, and Fe. For determination of the oxidation states of the elements, high-resolution XPS was conducted, and Fe 2p, O 1s, and C 1s spectra were obtained (FIG. 10H and FIGS. 6A and 6B). As shown in FIG. 10H, the binding energies at about 707 eV and about 722 eV were the characteristic doublets from Fe 2p_{3/2} and Fe 2p_{1/2} core-level electrons, confirming that the iron oxide present is Fe₃O₄. Two characteristic peaks of O is were observed for magnetic wood. The peak at about 529.2 eV was attributed to the C 1s for carbohydrates, which was also observed in the natural wood. The peak at about 526.8 eV was attributed to Fe₃O₄, which was absent in the natural wood and delignified wood.

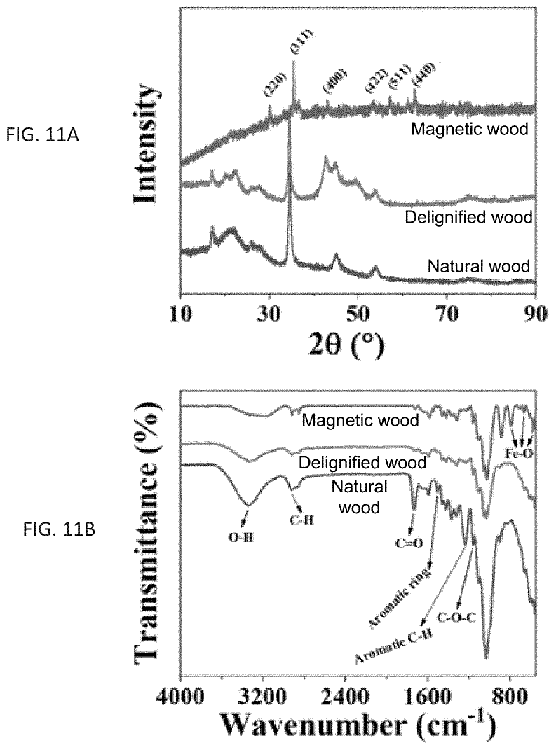

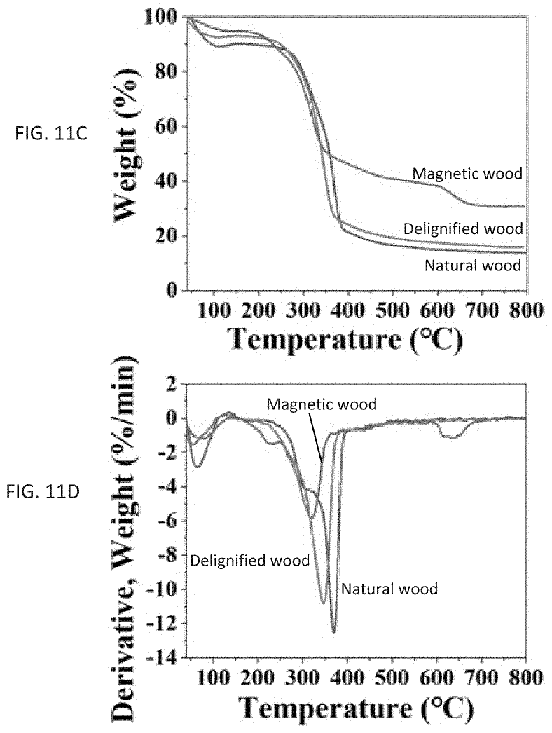

FIG. 11A shows the X-ray diffraction (XRD) patterns of the natural wood, delignified wood, and magnetic wood. Both natural wood and delignified wood displayed two primary diffraction peaks at 16.8° and 22.5°, which can be assigned to the (100) and (002) planes of cellulose, respectively. However, the characteristic peaks of cellulose were not obvious in the magnetic wood sample, which is attributed to the fact that iron oxide covers the wood substrate. The magnetic wood showed additional diffraction peaks at 2θ=30.2°, 35.6°, 43.2°, 53.6°, 57.1°, and 62.7°, corresponding to the (220), (311), (400), (422), (511), and (440) planes of Fe₃O₄ in a cubic phase. FIG. 11B shows the Fourier transform infrared (FTIR) spectra of the natural wood, delignified wood, and magnetic wood. The natural wood presented characteristic absorption peaks including 3335 cm⁻¹, 1642 cm⁻¹ (O—H stretching vibrations), 2920 cm⁻¹ (C—H stretching vibration), 1722 cm⁻¹ (C═O stretching vibrations), 1508 cm⁻¹ (the aromatic ring stretching vibrations of lignin), 1457 cm⁻¹ (C═O symmetric stretching vibrations), 1231 cm⁻¹ (aromatic C—H in-plane deformation assigned to lignin), and 1160 cm⁻¹ (C—O—C asymmetric stretching vibration), which is in agreement with previous literature. After lignin removal, the bands at approximately 1508 and 1231 cm⁻¹ became weaker or even disappeared, further indicating the degradation of light-absorbing lignin. When the Fe₃O₄ nanoparticles were added to the delignified wood, the stretching vibrations of Fe—O can be clearly seen at 576, 665, and 783 cm⁻¹. These results further confirm that the Fe₃O₄ nanoparticles were successfully deposited on the delignified wood. The introduction of magnetic Fe₃O₄ particles into the wood substrate was also indicated by thermogravimetric analysis (TGA), as shown in FIG. 11C and FIG. 11D. The simultaneous thermal analysis of natural wood, delignified wood, and magnetic wood were carried out under a N2 atmosphere. Two-stages of mass loss were observed in the natural wood and delignified wood. The first stage at approximately 100° C. was due to the elimination of moisture and the major mass loss of the natural wood in the range of 260-390° C. was caused by the pyrolysis of wood components including cellulose, hemicellulose, and lignin. The fact that 12.67 wt % residue mass remained after heating to 600° C. and no further mass loss occurred when the temperature was increased to 800° C. suggests the wood was converted to charcoal under the experimental temperature conditions. The major mass loss of the delignified wood occurred between 230-370° C., which is slightly lower than natural wood due to the removal of lignin. However, thermogravimetric (TG) curves of the magnetic wood were different from those of the natural wood and delignified wood. The mass loss in the temperature range of 210-340° C. was caused by the pyrolysis of wood components. More importantly, an extra decomposition step was observed starting at a temperature of approximately 600° C., which corresponds to the reduction reaction between Fe₃O₄ and the char obtained from the pyrolysis of wood. Notably, the weight of residues in the magnetic wood was 31.25 wt %, suggesting that the deposition of Fe₃O₄ minerals on the wood substrate was approximately 18.58 wt %. The differential thermal gravity (DTG) analysis was carried out as shown in FIG. 11D; wherein, the obvious peaks of the magnetic wood and delignified wood were weakened compared to those of the natural wood, indicating a lower rate of total weight loss for the magnetic wood. This effect could be explained by the fact that the wood components were likely to be shielded by the inorganic Fe₃O₄ nanoparticles, which prevented the wood components from being accessible to oxygen and thus reduced the rate of combustion.

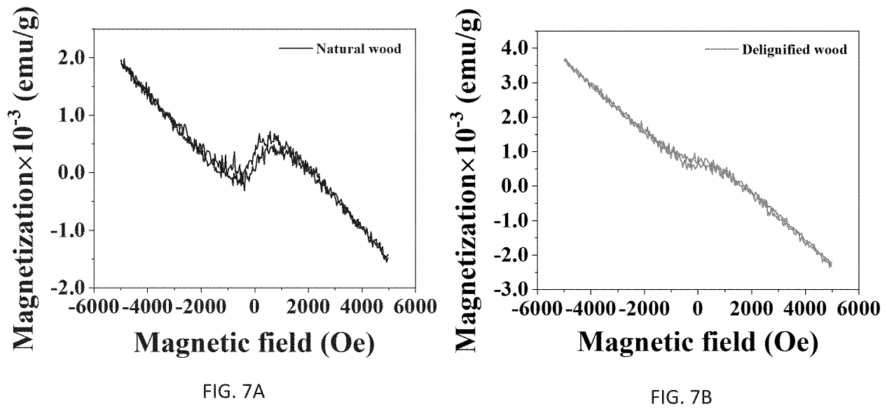

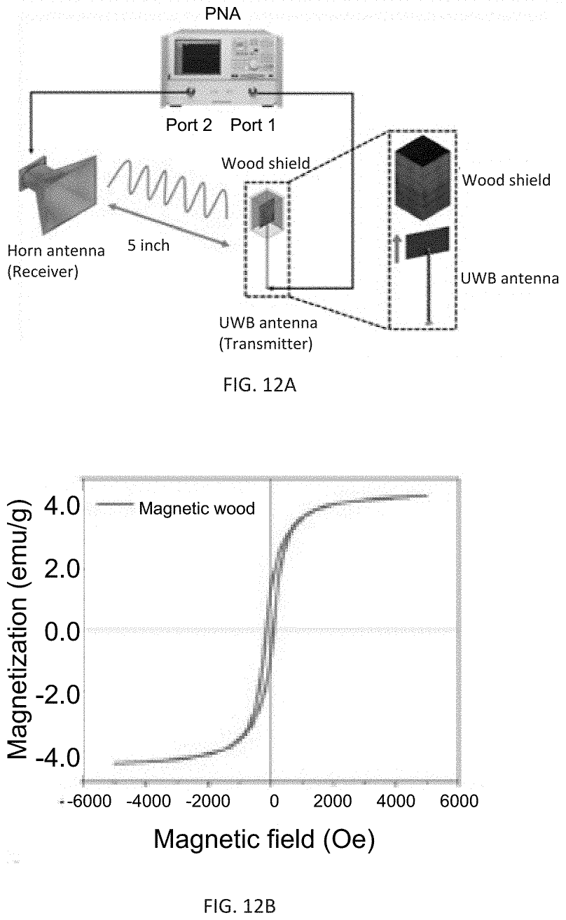

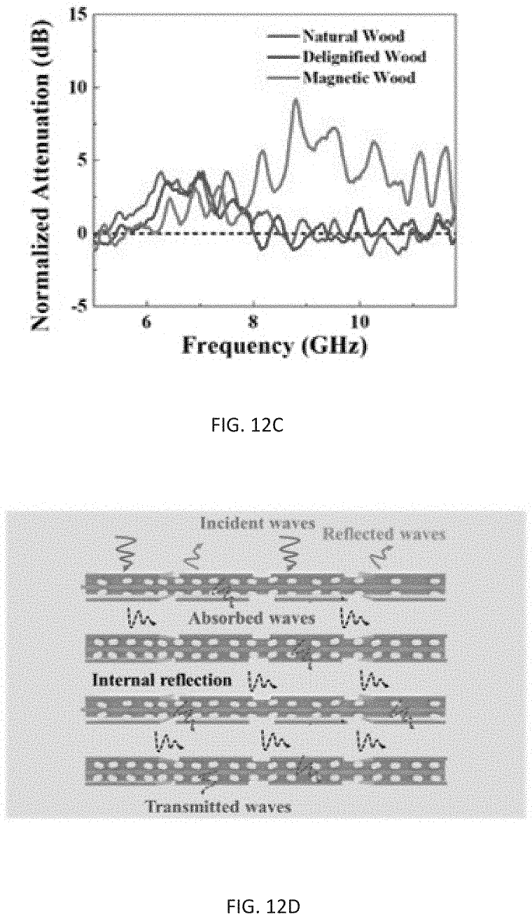

It is notable that the outstanding advantage of magnetic wood is its magnetic properties, which result in significantly enhanced EMI shielding performance. FIG. 12B shows the magnetization curves of magnetic wood measured by using a vibrating sample magnetometer (VSM) at room temperature. As seen in the FIG. 12B, typical magnetic hysteresis behavior with a saturation magnetization of 4.5 emu/g for the whole magnetic wood, and a coercive field of 131.3 Oe was observed in the magnetic wood. However, the natural wood and delignified wood were observed to have typical diamagnetic behavior, as expected (FIGS. 7A and 7B). Currently, strong EMI shielding material is in high demand for electronic devices. Further EMI shielding tests were carried out using a network analyzer (PNA, Agilent, E8364A), a commercial UWB (ultrawide band) antenna and a standard horn antenna. The detailed setup is shown in FIG. 12A, where the UWB antenna was covered by different types of wood shields and the horn antenna was used to receive signals coming from the UWB antenna. All tests were conducted in an anechoic chamber to avoid electromagnetic noise from the environment. The s-parameter was then calculated within the PNA using the following equations:

S₁₁=10*log₁₀(P₁ᵣ/P₁) (1)

S₂₁₌₁₀*log₁₀(P₂/P₁) (2)

where P₁ is the total power provided by the PNA, P₁ᵣ is the reflected power from the UWB antenna, and P₂ is the power received by the horn antenna.

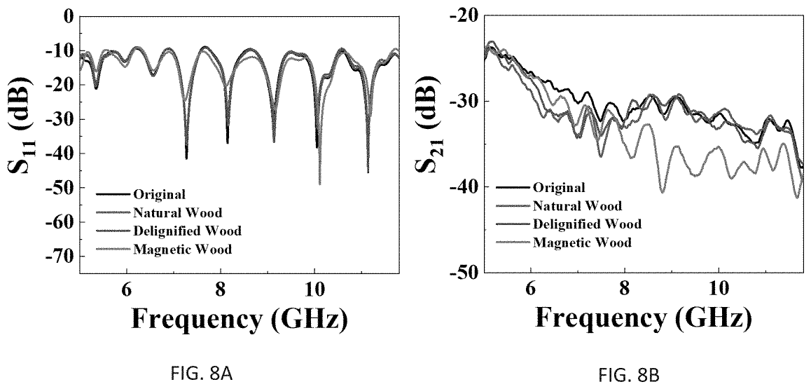

Frequency sweeps from approximately 5 to approximately 12 GHz were used to identify the EMI shielding properties of natural wood, delignified wood, and magnetic wood, as shown in FIGS. 8A and 8B. The return loss curves (S₁₁) for natural wood and delignified wood show very stable patterns as shown in FIG. 8A. Several spikes from delignified wood were observed due to its intrinsic material resonance. The use of the magnetic wood shield leads to a slight change in the S₁₁ graph, which is mainly caused by the microwave signal reflection from magnetic wood. The transmission loss is presented in FIG. 8B as S₂₁ data. Substantially enhanced signal strength attenuation by approximately 5 to approximately 10 dB (or approximately 7 to approximately 10-fold enhancement) can be observed across the X-band (approximately 8 to approximately 12 GHz) after applying the magnetic wood shield compared to the nonmagnetic wood shield. The substantial signal strength attenuation for magnetic wood indicates an excellent improvement in the EMI shielding effectiveness mainly due to the enhanced magnetic loss tangent of the magnetic wood compared to the nonmagnetic wood.

Without wishing to be bound by theory, the schematic diagram of the EMI shielding mechanism of magnetic wood is illustrated in FIG. 12D. As electromagnetic incident waves contact the top surface, some waves are immediately reflected. The remaining waves pass through the wood interconnected porous network, where they interact with the Fe₃O₄ nanoparticles deposited on the inner surface of the lumen walls in the wood, which results in electromagnetic wave attenuation due to the enhanced magnetic loss tangent of the magnetic wood. Further improvements to the magnetic properties may lead to enhanced EMI suppression capability.

Conclusion: In summary, a ready process of alternating incubation cycles assisted by sonication impregnation was introduced to transport a ferric salt precursor into the mesoporous wood substrate, leading to magnetic wood. Magnetic Fe₃O₄ nanoparticles were deposited into the porous 3D structured organic wood scaffold by an in situ mineralization. Due to its natural mesoporous and interconnected porous network structure as well as enhanced magnetic loss tangent, excellent EMI shielding effectiveness was achieved in the 3 mm thick magnetic wood, which show an approximately about 7 to approximately about 10× times improvement over its nonmagnetic counterpart, making the magnetic wood an attractive candidate as an electromagnetic wave shielding material. Both the wood and iron element are abundant on Earth, and the fabrication process is environmentally friendly and scalable. Furthermore, the obtained magnetic wood is construable and much lighter than bulk magnetic metal. Attributed to the abovementioned merits, this novel magnetic wood is highly attractive for large-scale EMI shielding applications for buildings and electronics in space, military, and civil.

Experimental Section

Materials and Chemicals: Hardwood is the wood featured in this work and the dimension of the wood slices is 50 mm×80 mm with a thickness of 3 mm. The chemicals used for removing the lignin from the wood were NaOH (>98 wt %, Sigma-Aldrich), Na₂SO₃ (98.5 wt %, Sigma-Aldrich), and H₂O₂ (30 wt % solution, Fisher Scientific). The chemicals used for impregnation to prepare the magnetic wood were FeSO₄.7H₂O (MW=278.01 g/mol, Fisher Scientific) and Na₂CO₃ (MW=105.99 g/mol, Fisher Scientific). The solvents used were ethanol (Fisher Scientific) and deionized (DI) water. All other chemicals were analytical grade and used as received without further purification.

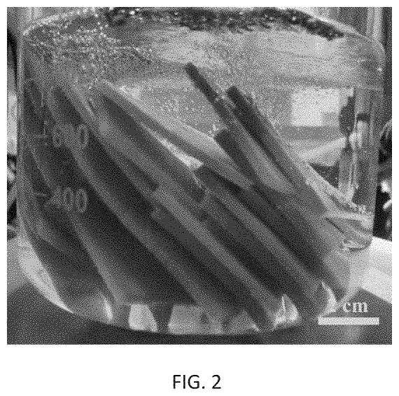

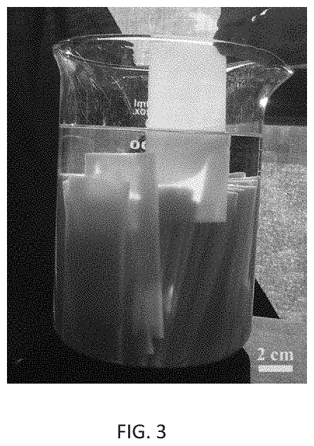

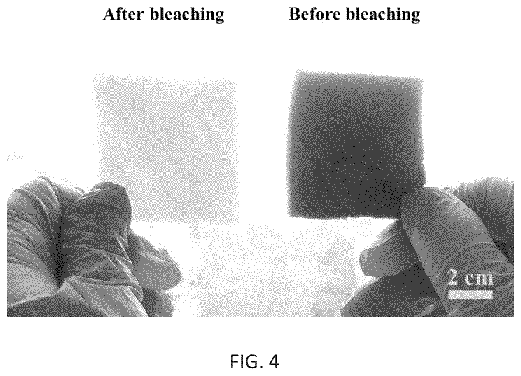

Wood Delignification Treatment: In the cooking process, the wood slices were immersed in a solution including NaOH (2.5 mol/L) and Na₂SO₃ (0.4 mol/L) and boiled for 12 hours (h). The slices were then rinsed in hot distilled water at least three times to remove most of the chemicals (FIG. 2). In the next bleaching process, the wood slices were then placed in the hot H₂O₂ (3.0 mol/L) and boiled without stirring. When the yellow color of the wood sample disappeared, the wood sample was removed and rinsed with cold water. The lignin-removed wood slices were then preserved in ethanol (FIG. 3).

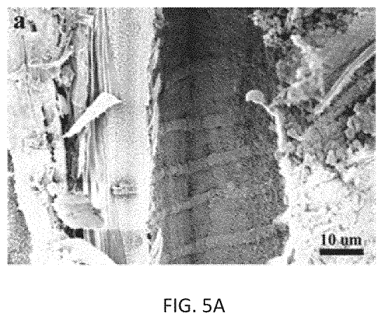

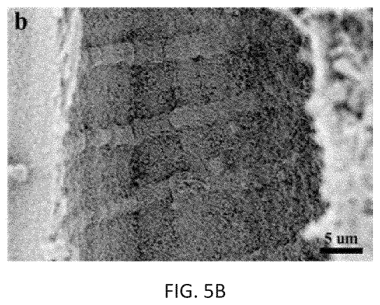

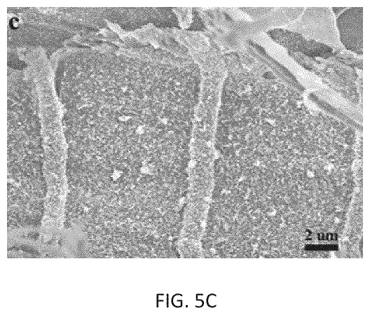

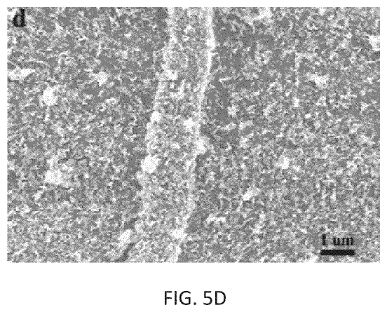

Fabrication of Magnetic Wood: Nanosized Fe₃O₄ particles firmly attached to the inner surface of the wood cell walls by performing alternating incubation cycles with FeSO₄ and Na₂CO₃ solutions. An incubation cycle is defined as immersing the lignin-removed wood slice in 0.5 mol/L FeSO₄ under agitation in a shaker for 24 h, sonication-assisted at least three times (10 min every time) to allow for in-depth diffusion into the porous wood structure, and then degassed for 10 minutes (min) to ensure full infiltration. The wood slice was then briefly rinsed in deionized (DI) water and then transferred to 0.5 mol/L Na₂CO₃ under agitation for another 24 h (sonication-assisted at least three times (10 min every time) to allow for in-depth diffusion into the porous wood structure, and then degassed for 10 min to ensure full infiltration). After being washed several times with DI water, the specimens were then dried in the oven while being pressed between two pieces of glass at 60° C. for 24 h. FIGS. 5a-d shows uniform distribution of the iron oxide particles.

Characterization: Scanning electron microscopy (SEM, S3700 Hitachi Ltd. Japan) was used to examine the morphology of the natural wood slices, delignified wood slices, and magnetic wood slices. The fixed samples were coated with a layer of approximately 30 Å thick gold. The accelerating voltage was 10 kV and the working distance was 11 mm. For elemental analysis of wood samples, energy dispersive X-ray spectroscopy (EDS) analysis was performed during SEM examination. The wood powder was deposited onto the KBr slice, and the Fourier Transform Infrared Spectroscopy (FTIR) spectra of the composite was recorded using a Nicolet FTIR 5700 spectrophotometer (Bruker, Germany) in transmission mode over the range of 500 to 4000 cm⁻¹ with a 4 cm⁻¹ resolution at 25° C. X-ray diffraction (XRD) tests were conducted on an X-ray diffractometer (UI tima IV, Japan) using Cu kα radiation at 40 kV and 30 mA. The scan was from a two theta of 5° to 40° at a step size of 0.05°. The thermal behavior of natural wood, delignified wood, and magnetic wood samples were measured using SDTQ600 (TA Instruments, USA) under nitrogen atmosphere from 40 to 800° C. at a heating rate of 10° C. min⁻¹. The X-ray Photoelectron Spectroscopy (XPS) was measured in an AXIS UltraDLD (Shimadzu, Japan) using an Al kα X-ray source and operating at 150 W. Each sample powder was dried in vacuo and 10 mg was weighed for each sample. Magnetic properties of the three kinds of wood samples were characterized with a vibrating sample magnetometer (Lake shore 7400). The measurement of the magnetization versus the applied magnetic field was conducted at 300 K. The EMI shielding property test was carried out by using a network analyzer (Agilent PNA E8364A), a commercial UWB (Ultra-wide-band) antenna and a standard horn antenna. The test samples were carefully cut into 22.86×10.16 mm² strips and assembled into a box.

### REFERENCES

1. Liang, C.; Song, P.; Qiu, H.; Zhang, Y; Ma, X.; Qi, F.; Gu, H.; Kong, J.; Cao, D.; Gu, J., Nanoscale 2019.
2. Lv, H.; Liang, X.; Ji, G.; Zhang, H.; Du, Y, ACS applied materials & interfaces 2015, 7 (18), 9776-9783.
3. Lou, Z.; Han, H.; Zhou, M.; Han, J.; Cai, J.; Huang, C.; Zou, J.; Zhou, X.; Zhou, H.; Sun, Z., ACS Sustainable Chemistry & Engineering 2017, 6 (1), 1000-1008.
4. Wu, H.; Wu, G.; Ren, Y; Yang, L.; Wang, L.; Li, X., Journal of Materials Chemistry C 2015, 3 (29), 7677-7690.
5. Gan, W.; Gao, L.; Zhan, X.; Li, J., RSC Advances 2015, 5 (57), 45919-45927.
6. Liang, C.; Song, P.; Qiu, H.; Huangfu, Y; Lu, Y; Wang, L.; Kong, J.; Gu, J., Composites Part A: Applied Science and Manufacturing 2019, 124, 105512.
7. Lou, Z.; Li, Y; Han, H.; Ma, H.; Wang, L.; Cai, J.; Yang, L.; Yuan, C.; Zou, J., ACS Sustainable Chemistry & Engineering 2018, 6 (11), 15598-15607.
8. Li, N.; Huang, Y; Du, F.; He, X.; Lin, X.; Gao, H.; Ma, Y; Li, F.; Chen, Y; Eklund, P. C., Nano letters 2006, 6 (6), 1141-1145.
9. Yang, Y; Gupta, M. C.; Dudley, K. L.; Lawrence, R. W., Advanced materials 2005, 17 (16), 1999-2003.
10. Song, J.; Chen, C.; Zhu, S.; Zhu, M.; Dai, J.; Ray, U.; Li, Y; Kuang, Y; Li, Y; Quispe, N., Nature 2018, 554 (7691), 224.
11. Chen, C.; Xu, S.; Kuang, Y; Gan, W.; Song, J.; Chen, G.; Pastel, G.; Liu, B.; Li, Y; Huang, H., Advanced Energy Materials 2019, 9 (9), 1802964.
12. Jiang, F.; Li, T.; Li, Y; Zhang, Y; Gong, A.; Dai, J.; Hitz, E.; Luo, W.; Hu, L., Advanced Materials 2018, 30 (1), 1703453.
13. Zhu, M.; Song, J.; Li, T.; Gong, A.; Wang, Y; Dai, J.; Yao, Y; Luo, W.; Henderson, D.; Hu, L., Advanced materials 2016, 28 (26), 5181-5187.
14. Yu, Z.-L.; Yang, N.; Zhou, L.-C.; Ma, Z.-Y; Zhu, Y-B.; Lu, Y-Y; Qin, B.; Xing, W.-Y; Ma, T.; Li, S.-C., Science advances 2018, 4 (8), eaat7223.
15. Yuan, Y; Sun, X.; Yang, M.; Xu, F.; Lin, Z.; Zhao, X.; Ding, Y; Li, J.; Yin, W.; Peng, Q., ACS applied materials & interfaces 2017, 9 (25), 21371-21381.
16. Yeniocak, M.; Goktas, O.; Colak, M.; Ozen, E.; Ugurlu, M., Maderas. Ciencia y tecnologia 2015, 17 (4), 711-722.
17. Hradil, D.; Grygar, T.; Hradilová, J.; Bezdička, P., Applied Clay Science 2003, 22 (5), 223-236.
18. Guskos, N.; Papadopoulos, G.; Likodimos, V; Patapis, S.; Yarmis, D.; Przepiera, A.; Przepiera, K.; Majszczyk, J.; Typek, J.; Wabia, M., Materials Research Bulletin 2002, 37 (6), 1051-1061.
19. Grygar, T.; Bezdička, P.; Hradil, D.; Doménech-Carbó, A.; Marken, F.; Pikna, L.; Cepriá, G., Analyst 2002, 127 (8), 1100-1107.
20. Merk, V.; Chanana, M.; Gaan, S.; Burgert, I., Holzforschung 2016, 70 (9), 867-876.
21. Mustoe, G.; Acosta, M., Geosciences 2016, 6 (2), 25.
22. Roberts, L., The Journal of Geology 1940, 48 (2), 212-213.
23. Guan, H.; Cheng, Z.; Wang, X., ACS nano 2018, 12 (10), 10365-10373.
24. Wu, Y; Wu, J.; Yang, F.; Tang, C.; Huang, Q., Polymers 2019, 11 (5), 776.
25. Vasileva, E.; Li, Y; Sychugov, I.; Mensi, M.; Berglund, L.; Popov, S., Advanced Optical Materials 2017, 5 (10), 1700057.
26. Li, Y; Yu, S.; Veinot, J. G.; Linnros, J.; Berglund, L.; Sychugov, I., Advanced Optical Materials 2017, 5 (1), 1600834.
27. Merk, V.; Chanana, M.; Gierlinger, N.; Hirt, A. M.; Burgert, I., ACS applied materials & interfaces 2014, 6 (12), 9760-9767.
28. Huang, Y; Chen, Y; Fan, X.; Luo, N.; Zhou, S.; Chen, S. C.; Zhao, N.; Wong, C. P., Small 2018, 14(31), 1801520.
29. Jeong, U.; Teng, X.; Wang, Y; Yang, H.; Xia, Y, Advanced Materials 2007, 19 (1), 33-60.
30. Gan, W.; Gao, L.; Xiao, S.; Zhang, W.; Zhan, X.; Li, J., Journal of materials science 2017, 52 (6), 3321-3329.
31. Gierlinger, N.; Goswami, L.; Schmidt, M.; Burgert, I.; Coutand, C.; Rogge, T.; Schwanninger, M., Biomacromolecules 2008, 9 (8), 2194-2201.
32. Cheng, Z.; Ye, H.; Cheng, F.; Li, H.; Ma, Y; Zhang, Q.; Natan, A.; Mukhopadhyay, A.; Jiao, Y; Li, Y, Advanced Materials Interfaces 2019, 6 (7), 1802010.
33. Ma, M.; Zhang, Y; Yu, W.; Shen, H.-y.; Zhang, H.-q.; Gu, N., Colloids and Surfaces A: physicochemical and engineering aspects 2003, 212 (2-3), 219-226.
34. Gan, W.; Gao, L.; Xiao, S.; Gao, R.; Zhang, W.; Li, J.; Zhan, X., Advanced Materials Interfaces 2017, 4 (22), 1700777.
35. Hu, B.; Zhao, C.; Jin, X.; Wang, H.; Xiong, J.; Tan, J., Colloids and Surfaces A: Physicochemical and Engineering Aspects 2015, 484, 278-287.
36. Wan, C.; Li, J., ACS Sustainable Chemistry & Engineering 2015, 3 (9), 2142-2152.
37. Shahzad, F.; Alhabeb, M.; Hatter, C. B.; Anasori, B.; Hong, S. M.; Koo, C. M.; Gogotsi, Y, Science 2016, 353 (6304), 1137-1140.
38. Chen, Y; Zhang, H. B.; Yang, Y; Wang, M.; Cao, A.; Yu, Z. Z., Advanced Functional Materials 2016, 26 (3), 447-455.
39. Wu, Y; Wang, Z.; Liu, X.; Shen, X.; Zheng, Q.; Xue, Q.; Kim, J.-K., ACS applied materials & interfaces 2017, 9 (10), 9059-9069.
40. Segmehl, J. S.; Laromaine, A.; Keplinger, T.; May-Masnou, A.; Burgert, I.; Roig, A., Journal of Materials Chemistry C 2018, 6 (13), 3395-3402.

The foregoing Example 1 has been described in Lightweight and Construable Magnetic Wood for Electromagnetic Interference Shielding, June 2020, Advanced Engineering Materials 22(10) DOI:10.1002/adem.202000257, the entirety of which is incorporated herein by reference.

### Example 2. Bioinspired Mineralization with Hydroxyapatite and Hierarchical Naturally Aligned Nanofibrillar Cellulose

Abstract: Cellulose and a nonclassical mineralization process was used to fabricate a bioinspired nanohybrid material that exhibited structural features and properties similar to those of human hard tissues. A hydrogel with highly compacted and aligned cellulose nanofibers was made. The cellulose hydrogel was thoroughly mineralized with hydroxyapatite nanocrystals, using poly(acrylic acid) as a soluble template for precursor minerals, which infiltrated the nanocompartments of the aligned cellulose nanofiber network. The ultrastructure and mechanical properties of the mineralized gels were strikingly similar to those of bone and dentin, which supports further use of cellulose-based fibrillary materials as affordable, biocompatible scaffolds for repair and regeneration of hard tissues. The versatility of the bioinspired mineralization processes used here can broaden the applications of these cellulosic nanohybrids.

Introduction: Scaffolds for repairing and regenerating human hard tissue defects which should mimic the chemical, structural, and mechanical properties of natural bone/dentin and have appropriate biochemical and nano/micro topographical features to trigger positive cell and tissue responses. The basic building block of bone and dentin is a mineralized nanostructure of collagen fibrils that are interpenetrated and surrounded by platelets of hydroxyapatite (HAp) nanocrystals. Nanoscale replication of the hierarchical nanoapatite assembly within the collagen fibril has been proven to contribute to the mechanical properties of biomimetic scaffolds and to be critical to the ability of the matrix to confer key biological properties, including cell proliferation and differentiation, formation of focal adhesions by cells, and cytoskeletal arrangement. Thus, biomimetic mineralization of the nanofibers, which mimics the chemical components and hierarchical structure of bone and dentin in micro and nanoscales, can produce an ideal candidate hybrid material for the repair and/or regeneration of damaged bones and/or teeth.

Various natural or synthetic polymer-based composites/hybrids, that is, HAp-mineralized biopolymers, including collagen matrix, poly(lactic acid) (PLA), poly(glycolic acid) (PGA), poly(lactic acid-co-glycolic acid) (PLGA), poly(ε-caprolactone) (PCL), chitosan, and elastin-like polypeptides, have been developed with biomagnetic hierarchical structures and unique mechanical properties. However, a hybrid material that incorporates nano and microstructural features of the extracellular matrix, with mechanical properties resembling those of natural hard tissues, and biocompatible, affordable, and readily available biopolymers has not been achieved to date. The use of cellulose and other nature-derived polymers presents an opportunity to develop these challenging biocomposites due to the wide array of manufacturing methods for these polymers as well as the variety of organisms from which they can be sourced.

Cellulose is a naturally occurring polymer with outstanding mechanical properties. Cellulose also exhibits excellent biocompatibility, abundance, biodegradability, nontoxicity, low-cost, and accessibility as it can be extracted from lignocellulosic biomass or synthesized from specific bacteria. The use of cellulose as a base component for fabricating hydrogels and other constructs for biomedical applications has gained significant attention. The functional groups in the backbone of cellulose and its derivatives have been used to manufacture biocompatible hydrogels with unique structures and multiple functionalities that enable their use in biomedical applications. However, the mechanical properties of nanocellulose hydrogels are limited, impeding their applicability in hard tissue regeneration. To overcome the low mechanical properties of cellulose scaffolds as well as to improve the bioactive properties for hard tissue regeneration, mineralization of cellulose hydrogels with HAp and other calcium phosphates has been actively investigated in recent years. For most of these studies, either simulated body fluids or other supersaturated solutions of Ca²⁺ and PO³⁻ were used as ionic sources for the nucleation and growth of calcium phosphate minerals on insoluble cellulose matrices. The minerals produced using these mineralizing solutions were deposited on or near to the surface of the cellulose matrix, forming microstructural aggregates of HAp nanocrystals. The resultant nanostructure of the nanocellulose/HAp hybrids are notably different from that of natural hard tissues and have relatively lower hardness.

During mineralization of the extracellular matrix of hard tissues in nature, insoluble collagen fibrils act as a structural template in which the interstices inside the fibrils serve as confined nanocompartments for mineral deposition. Thorough intrafibrillar mineralization of the structural matrix can be obtained in vitro using biomimetic methods. Polyanions stabilize prenucleation clusters that bind to and infiltrate the fibrillar collagen and subsequently transform into amorphous calcium phosphate and, finally, crystalline Hap with their direction parallel to the long axes of the collagen fibrils as in the case of bone. Poly(aspartic acid), poly(acrylic acid), and even some polycations have been used in in vitro biomimetic models as soluble active templates for collagen mineralization. However, few biopolymer-based fibrillary structures other than collagen have been biomineralized with HAp using this or similar biomimetic processes. The presence of nanocompartments in the structural matrix seems to be necessary for facilitating the penetration of the polyanion-stabilized amorphous clusters and confining the minerals inside the insoluble templating structure during transformation into the stable crystalline phase. This has limited the applicability of polymeric structures as alternative organic matrices in directing mineralization using processes that mimic the one for mineralizing collagen. Molecular self-assembly of the polymers that form the scaffold, such as those in collagen and elastin polymers, or controlled dense compaction of the fibrils in the structure can be exploited to provide the necessary nanocompartments and enable mineralization. In this work, a bioinspired hybrid hydrogel made of highly compacted and aligned cellulose nanofibers that was thoroughly mineralized with embedded HAp nanocrystals was fabricated. The obtained bioinspired hybrids exhibited structural features and properties similar to those of human hard tissues.

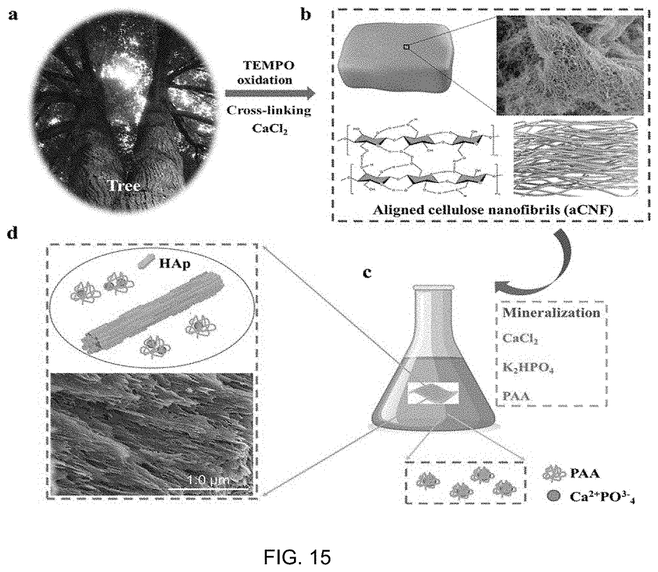

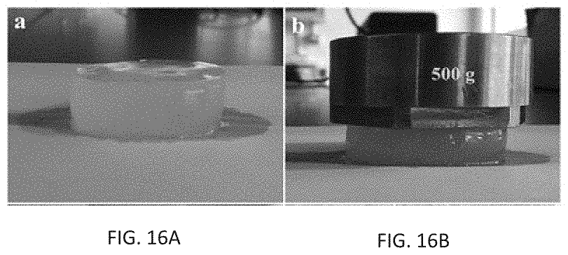

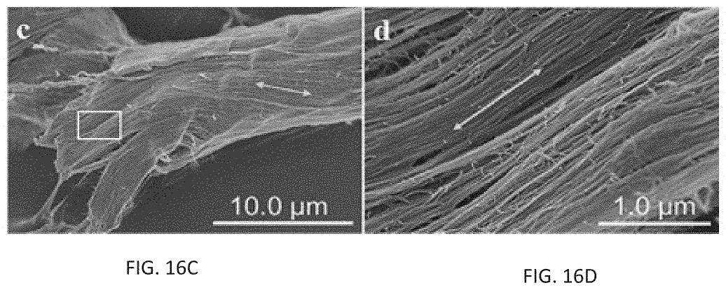

Results and Discussion: Nature-derived wood fiber has a hierarchical structure with one large microfiber composed of thousands of aligned nanofibers (FIGS. 15(a) and (b)). A hydrogel made of cellulose microfibers that were treated by (2,2,6,6-tetramethyl-1-piperidinyloxy) TEMPO-mediated oxidation and modest physical sonication. The C6 hydroxyl groups of the cellulose chain were partially oxidized to carboxyl groups, which have a lower zeta potential. During the fabrication process, the positive Ca²⁺ was used as a cross-linker between the negative carboxyl and hydroxyl groups on the cellulose chains, which significantly promoted gelation of the oxidized fibers, stabilizing their 3D structure. The hydrogel after CaCl₂) treatment was transparent and mechanically strong (FIG. 16A, FIG. 16B). There were still highly aligned cellulose nanofibers (aCNF) inside the individual microfiber (FIG. 15(a)). In this work, the biomimetic mineralization process (FIG. 15(c)) with CaCl₂), K₂HPO₄, and poly(acrylic acid) (PAA) to mineralize the aCNF was used, and thus, the fully mineralized aCNF (m-aCNF) composite was obtained (FIG. 15(d)).

Visualization by scanning electron microscopy (SEM) of the aCNF hydrogels revealed that these gels contained fibers of about 8-10 μm in diameter (FIG. 16C), which were composed of aligned nanocellulose fibril bundles (about 20 nm diameter) (FIG. 16D). This occurred because the microfiber is corrupted and partially disintegrated by TEMPO oxidation treatment and moderate sonication. However, the aligned nanofibers inside the microfiber remained unchanged. The alignment of the nanofibrils in the hydrogel is a preservation of the natural alignment in the cellulose as imparted by the plant cell wall from which it was derived. The alignment of the nanofibers generated a highly compacted fibrillary nanostructure in the aCNF gels with spaces between nanofibers of smaller dimensions than the diameter of the nanofibers.

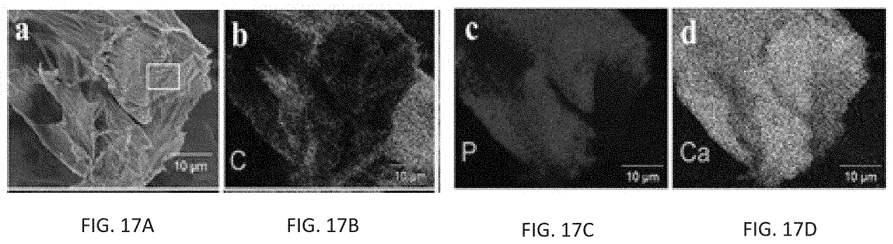

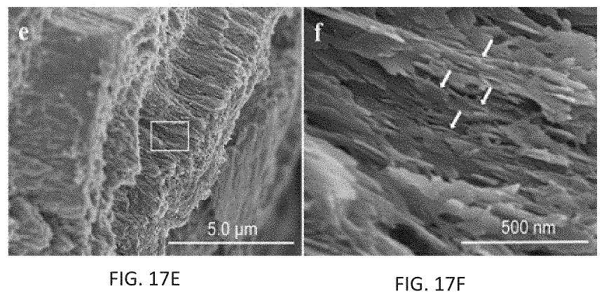

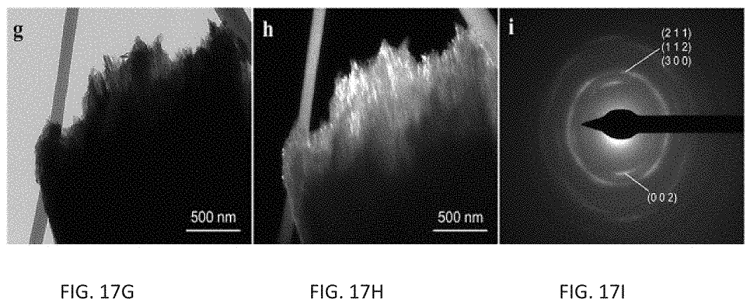

After 28 days of immersion in the biomimetic mineralizing solution (4.5 mM CaCl₂, 4.2 mM K₂HPO₄, 50 mg/L, 450 kDa PAA), the aCNF hydrogels were fully mineralized with a continuous network of minerals throughout the full section of the m-aCNF fibers. Twenty-eight days was the minimum period needed to obtain the m-aCNF gels. The minerals were tightly packed and thoroughly infiltrated the cellulose nano-fiber bundles (FIG. 15(d) and FIG. 17A and FIG. 17E). PAA has been used as an analog of noncollagenous proteins in in vitro biomimetic models for collagen mineralization to develop biomimetic scaffolds and constructs for bone and dentin tissue engineering. 50 mg/L. of PA A with a molecular weight of 450 kDa as these are the optimal conditions for obtaining effective and fast (i.e., within 1 day in solution) intrafibrillar mineralization of collagen gels was used. PAA has dual functions: it acts as both an inhibitor and a promoter of mineralization in these in vitro mineralizing systems. PAA molecular weight and concentration modulate the infiltration of the polymeric matrix by (i) providing solution stability (inhibition effect), that is, preventing spontaneous precipitation of HAp crystals and/or extrafibrillar mineralization of the polymer matrix and (ii) control over the number and growth of the PAA-stabilized mineral precursors that formed in solution (promoter effect) before entering the polymer matrix. A wide range of combinations of PAA molecular weight and concentration enable intrafibrillar mineralization of collagen and the same was expected for mineralization of the m-aCNF material. Even though the PAA molecular weight and concentration used might not be optimal for mineralizing aCNF hydrogels, these PAA properties proved to be in the appropriate range to obtain thorough mineralization.

The nanostructure of m-aCNF contained platelet-like nanocrystals of about 100 nm in length and about 50 nm in width, as visualized in SEM micrographs of the cross section of m-aCNF fibers (FIG. 17F). The crystals were aligned and packed along the cellulose nanofibers (FIG. 17F, arrows). The alignment and infiltration were further confirmed by transmission electron microscopy (TEM) micrographs. Cross-sectional view of an m-aCNF fiber (FIG. 17F) showed nanocrystals throughout the entire bundle of nanofibers. Dark-field TEM micrographs for the (002) plane also showed thorough infiltration of aligned crystals (FIG. 17H).

Further characterizations of the chemistry and structure of aCNF and m-aCNF materials, including energy-dispersive X-ray spectroscopy (EDS), selected area electron diffraction (SAED), X-ray diffraction (XRD), and attenuated total reflectance-Fourier transform infrared spectroscopy (ATR-FTIR) confirmed the existence of carbonated HAp nanocrystals within the cellulose fibers of the in-aCNF gels.

C, Ca, and P elemental mappings by EDS confirmed the thorough mineralization throughout the nanofiber bundle (FIG. 17A-D). The Ca/P ratio was 1.53 for the area analyzed, which was slightly lower than that of the stoichiometric HAp (1.67). This low Ca/P ratio suggested that the HAp minerals in m-aCNF were Ca-deficient, as is the case for the carbonated calcium-deficient HAp found in natural hard tissues (1.51-1.64).

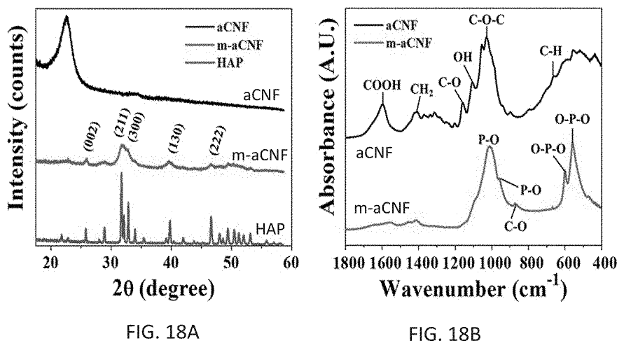

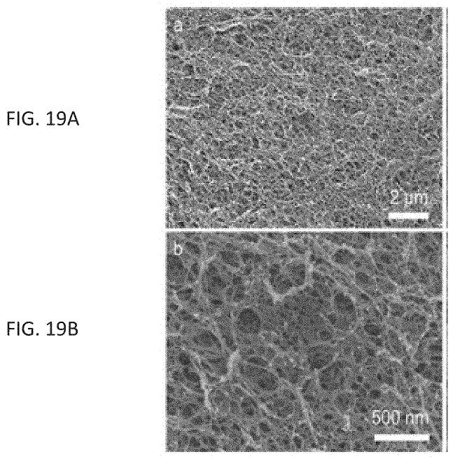

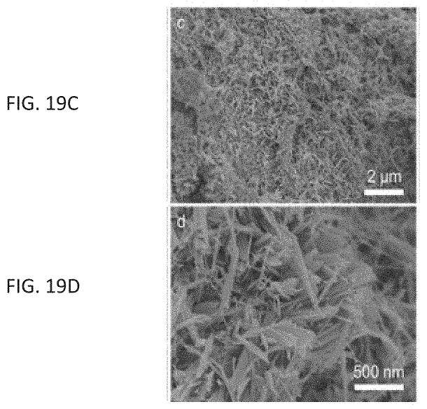

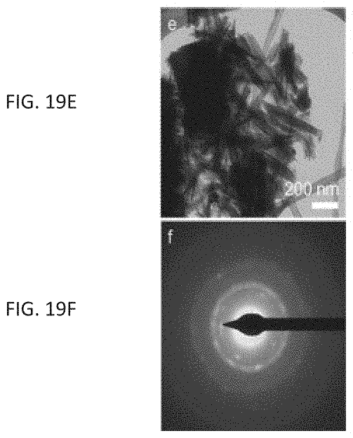

It was confirmed that the crystals infiltrating the m-aCNF gels were HAp by XRD (FIG. 18A), ATR-FTIR (FIG. 18B), and SAED (FIG. 17I). XRD patterns of nonmineralized aCNF displayed a characteristic native cellulose peak with broad diffraction at approximately 2θ=22.6°, which indicated a crystalline structure with (200) plane of cellulose I. XRD pattern of m-aCNF included peaks for the HAp (002), (211), (300), (130), and (222) planes. The XRD peaks for mineralized cellulose gels were broader than the peaks of the same planes for pure HAp, which is most likely due to the nanosize nature of the HAp crystals in m-aCNF gels (FIG. 17F-H). ATR-FTIR spectra for aCNF gels had characteristic adsorption bands of cellulose, that is, the C—O antisymmetric bridge stretching, —OH skeletal vibration, C—O—C pyranose ring skeletal vibration, CH2 symmetric bending, out-of-plane deformation of the C—H functional group, and asymmetrical carboxylate COO-vibration. The adsorption bands for the characteristic phosphate (556 and 600 cm⁻¹) and carbonate (870 cm⁻¹) groups of carbonated HAp were prominent in the spectra for m-aCNF materials. The major characteristic bands for P—O bonds in HAp at 958 and 1020 cm⁻¹ were overlapped with the bands for the C—O—C groups of the cellulose matrix. SAED analysis of the crystals also displayed the characteristic HAp patterns with arcing of the (002) planes, indicating that the HAp nanocrystals were aligned in the [001] direction parallel to the longitudinal axis of the cellulose fibrils (FIG. 17I). The oriented hybrid nanostructure in m-aCNF was strikingly similar to the ultrastructure of natural organic-inorganic hybrid composites with unique hierarchical structures like bone and dentin. CNF gels manufactured with an analogous process but without alignment of the cellulose nanofibers were also mineralized, but thorough infiltration of the cellulose fiber bundles and mineral orientation along the fibers were not achieved (FIG. 19).

Thus, the alignment of cellulose nanofibers in aCNF hydrogels appeared to be a key structural feature in the successful and thorough infiltration of minerals in the m-aCNF materials when using PAA as the mineral precursor stabilizer. The much smaller and aligned nanospaces of the aCNF gels in comparison to nonaligned CNF gels might play an analogous role in intrafibrillar mineralization of m-aCNF to that of gap zones in self-assembled fibrillary collagen structures in natural hard tissues. Nanocompartments also play a critical role during biomimetic intrafibrillar mineralization of synthetic collagen fibrillary structures and self-assembled fibers of elastin-like recombinant polymers.

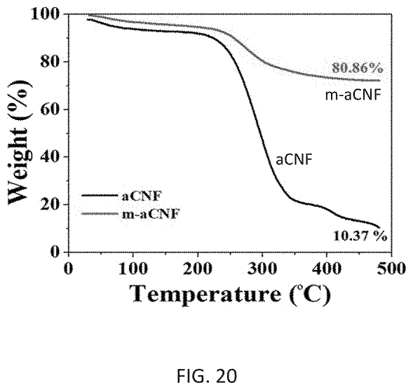

Thermogravimetric analysis (TGA) confirmed that the m-aCNF composite contained large amounts of minerals. The m-aCNF composite showed higher thermal stability during TGA experiments than nonmineralized aCNF (FIG. 20). Most of the mass loss in both samples occurred at the 225-350° C. heating range due to the thermal degradation and burn out of cellulosic polysaccharide. The aCNF gels also lost notable mass content due to degradation of the remaining organic material (oxygen-containing groups, that is, hydroxyl, carboxyl, and ether groups) into carbon residues between 350-480° C. Two exothermic reactions occurred, which were attributed to active flaming combustion and char oxidation. These carbon residues seemed to be stabilized by the minerals in m-aCNF samples and thus were not significantly degraded in this range of temperatures. The final remaining contents (mostly mineral in m-CNF but also salts and organic residues) at 480° C. were 80.86 and 10.37 weight percent (wt %) for m-aCNF and aCNF, respectively. The roughly 70 wt % mineral content in m-aCNF samples is, once again, comparable with the mineral content in natural hard tissues (ranging about 70-85 wt %) and other HAp-mineralized fibrillary synthetic collagen and elastin-based materials.

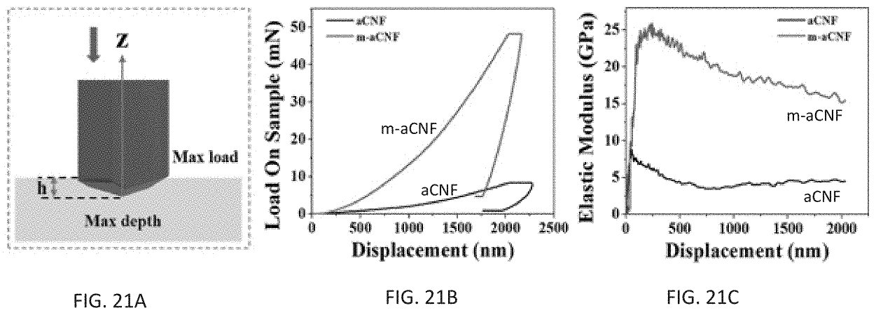

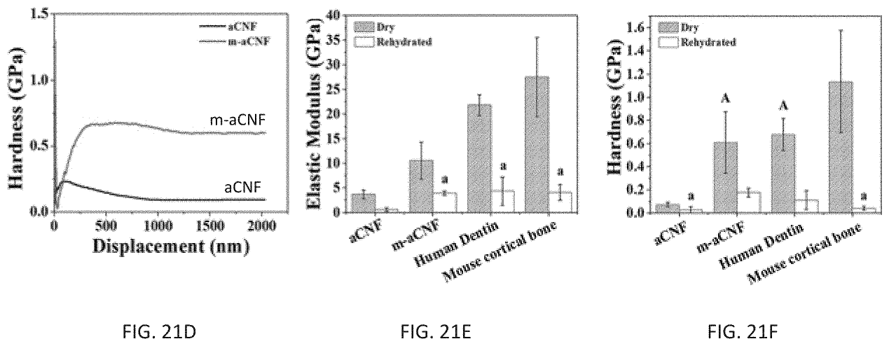

The highly ordered and highly mineralized structure of intrafibrillar mineralization at the nanoscale is considered to be the foundation of biomechanical properties of natural hard tissues. The elastic modulus and hardness of the m-aCNF nanohybrid structures by nanoindentation was determined. It was assessed that the mechanical properties of our mineralized cellulose-based hybrids after rehydration, that is, close to natural conditions, were comparable to those of mouse cortical bone and human dentin (FIG. 21). The nanomechanical test of different kinds of CNF samples is illustrated in FIG. 21A. Meanwhile, the representative nanoindentation load-displacement curves are shown in FIG. 21B. Values of elastic modulus in a dry state for dentin and cortical bone were significantly higher than those for m-aCNF samples, although in the same order of magnitude (FIG. 21C and FIG. 21E). Cortical bone hardness in a dry state was also significantly higher than dentin and m-aCNF hardness (FIG. 21D and FIG. 21F). However, when all materials were tested and compared in rehydrated conditions, the natural hard tissues and m-aCNF hybrids displayed mechanical properties with no significant differences. Similarly, it has been reported that in vitro intrafibrillarly mineralized collagen membranes in dry and rehydrated states have higher and lower mechanical properties, respectively, than m-aCNF. The greater effect of water on lowering mechanical properties of hard tissues and in vitro intrafibrillarly mineralized collagen membranes than of m-aCNF hybrids might be associated with a notably lower incorporation of water into m-aCNF than collagen-based mineralized materials. The more compact cellulose fiber bundles (about 10 μm in diameter) than reconstituted collagen fibers (100-200 nm in diameter) might leave less space for water infiltration after mineralization. The similar nanostructure and mechanical properties of m-aCNF hybrids and natural hard tissues in hydrated conditions support further use of cellulose-based fibrillary materials as affordable, versatile, and biocompatible scaffolds for repair and regeneration of hard tissues.

Conclusions: TEMPO-oxidized cellulose hydrogels with highly compact and well-aligned nanofibers were fabricated and mineralized with HAp crystals using a biomimetic method to obtain a hybrid nanocomposite with nanostructural features (composition, distribution, structure, orientation of crystals) and mineral content resembling those of natural hard tissues. The exceptional mechanical properties (elastic modulus and hardness) of m-aCNF nanohybrids were comparable to those of natural hard tissues, including human dentin and mouse cortical bone, in hydrated conditions. Thus, this nanocellulose-based biohybrid is a promising candidate material for hard tissue repair and regeneration. The versatility in the fabrication methods of cellulose could be utilized to tailor the structure and properties of hybrid cellulosic materials. Similarly, the bioinspired mineralization processes, such as the use of soluble templates to stabilize mineral precursors, may be used to produce cellulose-based hybrids with high contents of minerals other than HAp. The latter might expand the use of cellulosic nanohybrids beyond biomedicine.

Experimental Section

Fabrication of aCNF Hydrogel: Nanofibrillar cellulose hydrogel with a cellulose weight percentage of 1.44 was prepared from softwood pulp. First, 2 g of dry weight softwood pulp was added to 100 mL of DI water containing 0.032 g of TEMPO, 0.2 g of NaBr, and 6 mL of 12.5 wt % NaClO solution (Sigma-Aldrich, St. Louis, Mo., USA). NaOH (0.5 M) was added to maintain a pH==10.5 at ambient temperature. After 2 h, the pH of the resulting mixture showed no further change, and the reaction was terminated. The oxidized cellulose fibers dispersion was immersed in a 0.1 M CaCl₂) solution in a mold and sonicated for 10 min to initiate gelation. Finally, the gel precursor was left to stand at room temperature for 24 h to obtain well-formed hydrogels. The resulted cellulose hydrogel was gently taken out and washed with DI water.

Mineralization of aCNF: CaCl₂ (9 mM) and 4.2 mM K₂HPO₄ (Sigma-Aldrich, St. Louis, Mo., USA) solutions were prepared in a Tris-buffered saline (TBS) at pH 7.4 and 37° C. PAA with a molecular weight of 450 kDa (Sigma-Aldrich, St. Louis, Mo., USA) was used as a mineralizing agent and dissolved in a phosphate solution of 100 mg/L before being mixed with an equal volume of calcium counterion solution. Thus, a mineralization solution of PAA (450 kDa) at 50 mg/L concentration was prepared. Cellulose hydrogels were cut into 5×5×5 mm cubes and incubated in the aforementioned mineralizing solution at 37° C. with agitation. Mineralizing solutions were refreshed every 3 days. After 28 days, the cellulose hydrogel cubes were collected and rinsed with DI water twice. Cellulose hydrogel cubes were dried with serial dehydration in ethanol and critical point drying (Samdri-780A, tousimis, Rockville, Md., USA) for further characterization with nonmineralized specimens.

Scanning Electron Microscopy (SEM) and Transmission Electron Microscopy (TEM): The morphologies of the specimens were imaged with a field emission gun SEM (Hitachi SU8230, Tokyo, Japan) operated at an accelerating voltage of 3 kV. All specimens were sputter-coated with a 5 nm-thick iridium layer. For elemental analysis of the mineralized samples, energy-dispersive X-ray spectroscopy (EDS) analysis was performed during SEM examination. Mineralized cellulose hydrogels were crushed into fine-grained powders in liquid nitrogen, dispersed in ethanol, and dropped on a lacey carbon-coated Nickel TEM grid with a 200 mesh size. Samples were analyzed using a TEM (FEI Tecnai G2 Spirit BioTWIN, Thermo Fisher Scientific, Waltham, Mass., USA) operated at 120 kV in bright-field (BF), dark-field (DF), and selected area electron diffraction (SAED) modes.

Attenuated Total Reflectance-Fourier Transform Infrared Spectroscopy (ATR-FTIR): FTIR analysis of the dried aCNF gel and m-aCNF hybrid was performed using an FTIR spectrometer (Nicolet iS50, Thermo Fisher Scientific, Waltham, Mass., USA), equipped with a built-in diamond attenuated total reflection (ATR) for single-spot ATR measurement. Each spectrum was the result of signal-averaging of 32 scans at a resolution of 2 cm⁻¹ with a wavenumber range of 400 to 4000 cm⁻¹.

X-ray Diffraction (XRD): The crystal structure of aCNF, m-aCNF, and HAp disks was characterized using a microdiffractometer system with a two-dimensional area detector (AXS, Bruker, Billerica, Mass., USA) operated at 40 kV and 35 mA. The detector covered the angular range 2θ of 17.5 to 60°. The data was collected with two frames per collection time and 1500 s for each frame. The results were analyzed using JADE8 software (Materials Data Inc., JADE, Livermore, Calif., USA).

Thermogravimetric Analysis (TGA): The thermal behavior of the dried cellulose samples before and after mineralization was measured using a 409 PC (Netzsch STA, Selb, Germany). The samples were heated under a nitrogen atmosphere from room temperature up to 480° C. at a heating rate of 10° C. min⁻¹.

Nanoindentation: Mechanical properties of the aCNF and m-aCNF samples were examined using a nanoindentor (XP, MTS Systems Corporation, Eden Prairie, Minn., USA) equipped with a Berkovich tip at room temperature. TestWorks 4 software (MTS Systems Corporation, Eden Prairie, Minn., USA) was used to analyze the elastic modulus and hardness. The dried aCNF, m-aCNF, human dentin, and mouse cortical bone were embedded in epoxy resin, sectioned to reveal an indentation surface and polished with polishing papers (SiC; 600, 800, and 1200) and alumina slurries (1, 03, and 0.05 un). Cortical bone samples were obtained by sectioning the midshaft of one femur from a healthy wild type 9-week-old male mouse (courtesy of Professor Lincoln Potter, University of Minnesota, IACUC exempt). The human dentin samples were obtained from a pull of unidentified third molars with no apparent signs of decay that were extracted at the University of Minnesota, School of Dentistry Clinics (IRB exempt). The roots were removed from the crown and then cut perpendicularly to their longitudinal axis at the middle third from the crown. A total of at least seven indents were performed on the specimen surfaces. The maximum indentation depth was set at 2000 nm. For the rehydrated specimens, the embedded specimens were rehydrated in DI water overnight and covered with a piece of soaked tissue before the tests. Sectioned surfaces were kept wet, and at least seven indents were ran for each sample during nanoindentation tests. The Oliver-Pharr data analysis method was used to analyze the elastic modulus and hardness at the depth of 2000 nm. Analysis of the statistically significant differences on mechanical properties among groups was performed with one-way ANOVA with Turkey's multiple comparison post-hoc test. The level of statistical significance was set at p<0.05.

### REFERENCES

(1) Dimitriou, R.; Jones, E.; McGonagle, D.; Giannoudis, P. V. Bone Regeneration: Current Concepts and Future Directions. BMC Med. 2011, DOI: 10.1186/1741-7015-9-66.
(2) Liu, Y.; Luo, D.; Kou, X.-X.; Wang, X.-D.; Tay, F. R.; Sha, Y.-L.; Gan, Y.-H.; Zhou, Y.-H. Hierarchical Intrafibrillar Nanocarbonated Apatite Assembly Improves the Nanomechanics and Cytocompatibility of Mineralized Collagen. Adv. Funct. Mater. 2013, 1404.
(3) Li, Y.; Chen, X.; Fok, A.; Rodriguez-Cabello, J. C.; Aparicio, C. Biomimetic Mineralization of Recombinamer-Based Hydrogels toward Controlled Morphologies and High Mineral Density. ACS Appl. Mater. Interfaces 2015, 25784.
(4) Lanao, R. P. F.; Jonker, A. M., Wolke, J. G. C.; Jansen, J. A.; van Hest, J. C. M.; Leeuwenburgh, S. C. G. Physicochemical Properties and Applications of Poly(Lactic-Co-Glycolic Acid) for Use in Bone Regeneration. Tissue Eng., Part B 2013, 380.
(5) Rezwan, K.; Chen, Q. Z.; Blaker, J. J.; Boccaccini, A. R. Biodegradable and Bioactive Porous Polymer/Inorganic Composite Scaffolds for Bone Tissue Engineering. Biomaterials 2006, 3413.
(6) Li, Y.; Rodriguez-Cabello, J. C.; Aparicio, C. Intrafibrillar Mineralization of Self-Assembled Elastin-Like Recombinamer Fibrils. ACS Appl. Mater. Interfaces 2017, 5838.
(7) Schneider, O. D.; Loher, S.; Brunner, T. J.; Uebersax, L.; Simonet, M.; Grass, R. N.; Merkle, H. P.; Stark, W. J. Cotton Woollike Nanocomposite Biomaterials Prepared by electrospinning: In vitro bioactivity and Osteogenic Differentiation of Human Mesenchymal Stem Cells. J. Biomed. Mater. Res., Part B 2008, 350.
(8) Chen, J.; Pan, P.; Zhang, Y.; Zhong, S.; Zhang, Q. Preparation of Chitosan/Nano Hydroxyapatite Organic-Inorganic Hybrid Microspheres for Bone Repair. Colloids Surf., B 2015, 401.
(9) El-Fiqi, A.; Seo, S. J.; Kim, H. W. Mineralization of Fibers for Bone Regeneration. In Biomineralization and Biomaterials: Fundamentals and Applications; Woodhead Publishing: 2015, DOI: 10.1016/B978-1-78242-338-6.00016-8.
(10) Cheng, Z.; Yang, R.; Liu, X.; Liu, X.; Chen, H. Green Synthesis of Bacterial Cellulose via Acetic Acid Pre-Hydrolysis Liquor of Agricultural Corn Stalk Used as Carbon Source. Bioresour. Technol. 2017, 8.
(11) Cheng, Z.; Ma, Y.; Yang, L.; Cheng, F.; Huang, Z.; Natan, A.; Li, H.; Chen, Y.; Cao, D.; Huang, Z.; Wang, Y.; Liu, Y.; Yang, R.; Zhu, H. Plasmonic-Enhanced Cholesteric Films: Coassembling Anisotropic Gold Nanorods with Cellulose Nanocrystals. Adv. Opt. Mater. 2019, 1801816.
(12) Li, H.; Cheng, Z.; Zhang, Q.; Natan, A.; Yang, Y.; Cao, D.; Zhu, H. Bacterial-Derived, Compressible, and Hierarchical Porous Carbon for High-Performance Potassium-Ion Batteries. Nano Lett. 2018, 7407.
(13) Fu, L. H.; Qi, C.; Ma, M. G., Wan, P. Multifunctional Cellulose-Based Hydrogels for Biomedical Applications. J. Mater. Chem. B 2019, 1541.
(14) Wan, Y. Z.; Hong, L.; Jia, S. R.; Huang, Y.; Zhu, Y.; Wang, Y. L.; Jiang, H. J. Synthesis and Characterization of Hydroxyapatite-Bacterial Cellulose Nanocomposites. Compos. Sci. Technol. 2006, 1825.
(15) Busuioc, C.; Stroescu, M.; Stoica-Guzun, A.; Voicu, G.; Jinga, S.-I. Fabrication of 3D Calcium Phosphates Based Scaffolds Using Bacterial Cellulose as Template. Ceram. Int. 2016, 15449.
(16) Duarte, E. B.; das Chagas, B. S.; Andrade, F. K.; Brigida, A. I. S.; Borges, M. F.; Muniz, C. R.; Souza Filho, M. de S. M.; Morais, J. P. S.; Feitosa, J. P. A.; Rosa, M. F. Production of Hydroxyapatite-bacterial Cellulose Nanocomposites from Agroindustrial Wastes. Cellulose 2015, 3177.
(17) Torgbo, S.; Sukyai, P. Bacterial Cellulose-Based Scaffold Materials for Bone Tissue Engineering. Appl. Mater. Today. 2018, 34.
(18) Salama, A. Cellulose/Calcium Phosphate Hybrids: New Materials for Biomedical and Environmental Applications. Int. J. Biol. Macromol. 2019, 606.
(19) Abouzeid, R. E.; Khiari, R.; Beneventi, D.; Dufresne, A. Biomimetic Mineralization of Three-Dimensional Printed Alginate/TEMPO-Oxidized Cellulose Nanofibril Scaffolds for Bone Tissue Engineering. Biomacromolecules 2018, 4442.
(20) Joshi, M. K.; Pant, H. R.; Tiwari, A. P.; Maharjan, B.; Liao, N.; Kim, H. J.; Park, C. H.; Kim, C. S. Three-Dimensional Cellulose Sponge: Fabrication, Characterization, Biomimetic Mineralization, and in Vitro Cell Infiltration. Carbohydr. Polym. 2016, 154.
(21) Fragal, E. H.; Cellet, T. S. P.; Fragal, V. H.; Companhoni, M. V. P.; Ueda-Nakamura, T.; Muniz, E. C.; Silva, R.; Rubira, A. F. Hybrid Materials for Bone Tissue Engineering from Biomimetic Growth of Hydroxiapatite on Cellulose Nanowhiskers. Carbohydr. Polym. 2016, 734.
(22) Reznikov, N.; Bilton, M.; Lari, L.; Stevens, M. M.; Kroger, R. Fractal-like Hierarchical Organization of Bone Begins at the Nanoscale. Science 2018, eaao2189.
(23) Nudelman, F.; Pieterse, K.; George, A.; Bomans, P. H. H.; Friedrich, H.; Brylka, L. J.; Hilbers, P. A. J.; De With, G.; Sommerdijk, N. A. J. M. The Role of Collagen in Bone Apatite Formation in the Presence of Hydroxyapatite Nucleation Inhibitors. Nat. Mater. 2010, 1004.
(24) Colfen, H. A Crystal-Clear View. Nat. Mater. 2010, 960.
(25) Jee, S. S.; Thula, T. T.; Gower, L. B. Development of Bone-like Composites via the Polymer-Induced Liquid-Precursor (PILP) Process. Part 1: Influence of Polymer Molecular Weight. Acta Biomater. 2010, 3676.
(26) Niu, L. N.; Jee, S. E.; Jiao, K.; Tonggu, L.; Li, M.; Wang, L.; Yang, Y. D.; Bian, J. H.; Breschi, L.; Jang, S. S.; Chen, J. H.; Pashley, D. H.; Tay, F. R. Collagen Intrafibrillar Mineralization as a Result of the Balance between Osmotic Equilibrium and Electroneutrality. Nat. Mater. 2017, 370.
(27) Yang, L.; Mukhopadhyay, A.; Jiao, Y.; Yong, Q.; Chen, L.; Xing, Y.; Hamel, J.; Zhu, H. Ultralight, Highly Thermally Insulating and Fire Resistant Aerogel by Encapsulating Cellulose Nanofibers with Two-Dimensional MoS2. Nanoscale 2017, 11452.
(28) Cao, D.; Xing, Y.; Tantratian, K.; Wang, X.; Ma, Y.; Mukhopadhyay, A.; Cheng, Z.; Zhang, Q.; Jiao, Y.; Chen, L.; Zhu, H. 3D Printed High-Performance Lithium Metal Microbatteries Enabled by Nanocellulose. Adv. Mater. 2019, 1807313.
(29) Dippold, D.; Cai, A.; Hardt, M.; Boccaccini, A. R.; Horch, R.; Beier, J. P.; Schubert, D. W. Novel Approach towards Aligned PCLCollagen Nanofibrous Constructs from a Benign Solvent System. Mater. Sci. Eng. C 2017, 278.
(30) Qi, Y.; Ye, Z.; Fok, A.; Holmes, B. N.; Espanol, M.; Ginebra, M. P.; Aparicio, C. Effects of Molecular Weight and Concentration of Poly(Acrylic Acid) on Biomimetic Mineralization of Collagen. ACS Biomater. Sci. Eng. 2018, 2758.
(31) Huang, S.-C.; Naka, K.; Chujo, Y. Effect of Molecular Weights of Poly(Acrylic Acid) on Crystallization of Calcium Carbonate by the Delayed Addition Method. Polym. J. 2008, 154.
(32) Kuhn, L. T.; Grynpas, M. D.; Rey, C. C.; Wu, Y.; Ackerman, J. L.; Glimcher, M. J. A Comparison of the Physical and Chemical Differences between Cancellous and Cortical Bovine Bone Mineral at Two Ages. Calcif. Tissue Int. 2008, 146.
(33) Rythén, M.; Sabel, N.; Dietz, W.; Robertson, A.; Norén, J. G. Chemical Aspects on Dental Hard Tissues in Primary Teeth from Preterm infants. Eur. J. Oral Sci. 2010, 389.
(34) Zhao, Y.; Moser, C.; Lindström, M. E.; Henriksson, G.; Li, J. Cellulose Nanofibers from Softwood, Hardwood, and Tunicate: Preparation-Structure-Film Performance Interrelation. ACS Appl. Mater. Interfaces 2017, 13508.
(35) Cheng, Z.; Ye, H.; Cheng, F.; Li, H.; Ma, Y.; Zhang, Q.; Natan, A.; Mukhopadhyay, A.; Jiao, Y.; Li, Y., Liu, Y.; Zhu, H. Tuning Chiral Nematic Pitch of Bioresourced Photonic Films via Coupling Organic Acid Hydrolysis. Adv. Mater. Interfaces 2019, 1802010.
(36) Jonoobi, M.; Khazaeian, A.; Tahir, P. M.; Azry, S. S.; Oksman, K. Characteristics of Cellulose Nanofibers Isolated from Rubberwood and Empty Fruit Bunches of Oil Palm Using Chemo-Mechanical Process. Cellulose 2011, 1085.
(37) Berzina-Cimdina, L.; Borodajenko, N. Research of Calcium Phosphates Using Fourier Transform Infrared Spectroscopy. In Infrared Spectroscopy—Materials Science, Engineering and Technology; BoD-Books on Demand, 2012; DOI: 10.5772/36942.
(38) Weiner, S.; Traub, W. Bone Structure: From Angstroms to Microns. FASEB J. 1992, 879.
(39) Fathy, M.; Abdel Moghny, T.; Mousa, M. A.; El-Bellihi, A. H. A. A.; Awadallah, A. E. Absorption of Calcium Ions on Oxidized Graphene Sheets and Study Its Dynamic Behavior by Kinetic and Isothermal Models. Appl. Nanosci. 2016, 6, 1105-1117.
(40) Lee, H. L.; Chen, G. C.; Rowell, R. M. Thermal Properties of Wood Reacted with a Phosphorus Pentoxide-Amine System. J. Appl. Polym. Sci. 2004, 2465.
(41) Bloebaum, R. D.; Skedros, J. G.; Vajda, E. G.; Bachus, K. N.; Constantz, B. R. Determining Mineral Content Variations in Bone Using Backscattered Electron Imaging. Bone 1997, 485.
(42) Thula, T. T.; Rodriguez, D. E.; Lee, M. H.; Pendi, L.; Podschun, J.; Gower, L. B. In Vitro Mineralization of Dense Collagen Substrates: A Biomimetic Approach toward the Development of Bone-Graft Materials. Acta Biomater. 2011, 3158.
(43) Jiao, K.; Niu, L. N.; Ma, C. F.; Huang, X. Q.; Pei, D. D.; Luo, T.; Huang, Q.; Chen, J. H.; Tay, F. R. Complementarity and Uncertainty in Intrafibrillar Mineralization of Collagen. Adv. Funct. Mater. 2016, 6858.
(44) Gao, H.; Ji, B.; Jager, I. L.; Arzt, E.; Fratzl, P. Materials Become Insensitive to Flaws at Nanoscale: Lessons from Nature. Proc. Natl. Acad. Sci. U.S.A. 2003, 5597.
(45) Weiner, S.; Wagner, H. D. THE MATERIAL BONE: Structure-Mechanical Function Relations. Annu. Rev. Mater. Sci. 1998, 271.
(46) Li, Y.; Thula, T. T.; Jee, S.; Perkins, S. L.; Aparicio, C.; Douglas, E. P.; Gower, L. B. Biomimetic Mineralization of Woven Bone-like Nanocomposites: Role of Collagen Cross-Links. Biomacromolecules 2012, 13, 49-59.
(47) Farhadi-Khouzani, M.; Schütz, C.; Durak, G. M.; Fornell, J.; Sort, J.; Salazar-Alvarez, G.; Bergstrom, L.; Gebauer, D. A CaCO3/Nanocellulose-Based Bioinspired Nacre-like Material. J. Mater. Chem. A 2017, 16128.
(48) Liu, X.; Zhou, Y.; Pei, C. Mimetic Biomineralization Matrix Using Bacterial Cellulose Hydrogel and Egg White to Prepare Various Morphologies of CaCO3. Cryst Eng Comm 2018, 4536.
(49) Kuo, D.; Nishimura, T.; Kajiyama, S.; Kato, T. Bioinspired Environmentally Friendly Amorphous CaCO3-Based Transparent Composites Comprising Cellulose Nanofibers. ACS Omega 2018, 12722.

The foregoing Example 2 has been described in Bioinspired Mineralization with Hydroxyapatite and Hierarchical Naturally Aligned Nanofibrillar Cellulose, Yipin Qi, Zheng Cheng, Zhou Ye, Hongli Zhu, and Conrado Aparicio, ACS Applied Materials & Interfaces, 2019, 11 (31), 27598-27604 DOI: 10.1021/acsami.9b09443, the entirety of which is incorporated herein by reference.

The teachings of all patents, published applications and references cited herein are incorporated by reference in their entirety.

While example embodiments have been particularly shown and described, it will be understood by those skilled in the art that various changes in form and details may be made therein without departing from the scope of the embodiments encompassed by the appended claims.

1. A composition comprising wood and an inorganic magnetic material which is uniformly distributed throughout the wood.

2. The composition of claim 1, wherein the wood is delignified.

3. (canceled)

4. The composition of claim 1, wherein the inorganic magnetic material is selected from a transition metal, rare earth element, a salt or mineral thereof, or a combination of any the foregoing.

5. (canceled)

6. The composition of claim 1, wherein the inorganic magnetic material is selected from iron oxide, nickel oxide, copper oxide, cobalt oxide, a salt or mineral thereof, or a combination of any of the foregoing.

7. The composition of claim 1, wherein the inorganic magnetic material is iron oxide.

8. (canceled)

9. The composition of claim 1, wherein the composition is between about 1% by weight inorganic material and about 50% by weight inorganic magnetic material.

10. (canceled)

11. The composition of claim 1, wherein the composition shows at least about five times enhanced electromagnetic wave attenuation across X-band 8-12 GHz compared to natural wood.

12. (canceled)

13. (canceled)

14. The composition of claim 1, wherein the composition further comprises one or more additional dyes or pigments.

15. A process of preparing a composition comprising wood and an inorganic magnetic material which is uniformly distributed throughout the wood, the process comprising mineralizing the wood with the inorganic magnetic material.

16. The process of claim 15, comprising delignifying the wood, thereby forming delignified wood; and mineralizing the delignified wood with the inorganic magnetic material.

17. The process of claim 15, wherein mineralizing the wood comprises submerging the wood in a liquid medium comprising the inorganic magnetic material, or a precursor thereof; and sonicating the wood in the liquid medium.

18. The process of claim 17, wherein the inorganic magnetic material, or a precursor thereof, comprises a transition metal, rare earth element, a salt or mineral thereof, or a combination of any the foregoing.

19. (canceled)

20. The process of claim 17, wherein the inorganic magnetic material, or a precursor thereof, comprises iron oxide, nickel oxide, copper oxide, cobalt oxide, a salt or mineral thereof, or a combination of any of the foregoing.

21. The process of claim 17, wherein the inorganic magnetic material, or a precursor thereof, comprises iron oxide.

22. The process of claim 17, wherein the liquid medium comprises Fe₃SO₄ and water.

23. The process of claim 17, wherein delignifying the wood comprises treating the wood with a solution comprising a strong base, and bleaching the wood.

24. The process of claim 23, wherein the solution comprising a strong base comprises NaOH and Na₂SO₃ in water.

25. The process of claim 23, wherein bleaching the wood comprises boiling the wood in a solution of H₂O₂ in water.

26. A method for providing electromagnetic interference shielding, comprising providing a composition comprising wood and an inorganic magnetic material which is uniformly distributed throughout the wood t between a source of electromagnetic radiation and a space to be shielded from the electromagnetic radiation, thereby shielding the space from the electromagnetic radiation.

27. The method of claim 26, wherein the composition is in the form of construction material or a structure.
